(19) United States
(12) Patent Application Publication
(10) Pub. No.: US 2026/0030951 A1
(43) Pub. Date: Jan. 29, 2026

(54) ROTATING MONITOR HINGE

(71) Applicant: Aristocrat Technologies Australia Pty Limited, North Ryde (AU)

(72) Inventors: Deepak Chaudhari, North Parramatta (AU); Prabhakar Mutukundu, Lidcombe (AU); Martin Mirakhour, Castle Hill (AU)

(21) Appl. No.: 18/807,257

(22) Filed: Aug. 16, 2024

Related U.S. Application Data
(60) Provisional application No. 63/676,181, filed on Jul. 26, 2024.

(51) Int. Cl. G07F 17/32; H05K 5/02

(52) U.S. Cl. CPC G07F 17/3216; H05K 5/0226

(57) ABSTRACT

Hinge assemblies for electronic gaming machines are provided. Some electronic gaming machines have a cabinet defining an internal compartment and an opening that provides access to the internal compartment, and having a stationary side panel at least partially defining the internal compartment and opening and having a first edge along a first axis, a door configured to support one or more display devices and having a door side panel with a second edge parallel to the first axis; and a hinge assembly having a stationary arm structure having a first portion positioned in the internal compartment and connected to the cabinet, and a second portion extending through the opening at a first point and having a distal end outside the internal compartment with a first pivot point, and a rotation bracket connected to the door and having a second pivot point.

### BACKGROUND

Electronic gaming machines (“EGMs”) or gaming devices provide a variety of wagering games such as slot games, video poker games, video blackjack games, roulette games, video bingo games, keno games and other types of games that are frequently offered at casinos and other locations. Play on EGMs typically involves a player establishing a credit balance by inputting money, or another form of monetary credit, and placing a monetary wager (from the credit balance) on one or more outcomes of an instance (or single play) of a primary or base game. In some cases, a player may qualify for a special mode of the base game, a secondary game, or a bonus round of the base game by attaining a certain winning combination or triggering event in, or related to, the base game, or after the player is randomly awarded the special mode, secondary game, or bonus round. In the special mode, secondary game, or bonus round, the player is given an opportunity to win extra game credits, game tokens or other forms of payout. In the case of “game credits” that are awarded during play, the game credits are typically added to a credit meter total on the EGM and can be provided to the player upon completion of a gaming session or when the player wants to “cash out.”

“Slot” type games are often displayed to the player in the form of various symbols arrayed in a row-by-column grid or matrix. Specific matching combinations of symbols along predetermined paths (or paylines) through the matrix indicate the outcome of the game. The display typically highlights winning combinations/outcomes for identification by the player. Matching combinations and their corresponding awards are usually shown in a “pay-table” which is available to the player for reference. Often, the player may vary his/her wager to include differing numbers of paylines and/or the amount bet on each line. By varying the wager, the player may sometimes alter the frequency or number of winning combinations, frequency or number of secondary games, and/or the amount awarded.

Typical games use a random number generator (RNG) to randomly determine the outcome of each game. The game is designed to return a certain percentage of the amount wagered back to the player over the course of many plays or instances of the game, which is generally referred to as return to player (RTP). The RTP and randomness of the RNG ensure the fairness of the games and are highly regulated. Upon initiation of play, the RNG randomly determines a game outcome and symbols are then selected which correspond to that outcome. Notably, some games may include an element of skill on the part of the player and are therefore not entirely random.

Electronic gaming machines are complex devices with display devices and are often housed within cabinets having multiple access points in the form of doors or trays that may be opened or slid out in order to access internal components, cables, connectors, etc.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

In some embodiments, an electronic gaming machine. The electronic gaming machine may have a cabinet defining an internal compartment and an opening that provides access to the internal compartment, and having a stationary side panel at least partially defining the internal compartment and opening and having a first edge along a first axis, a door configured to support one or more display devices and having a door side panel with a second edge parallel to the first axis, and a hinge assembly having a stationary arm structure having a first portion positioned in the internal compartment and connected to the cabinet, and a second portion extending through the opening at a first point and having a distal end outside the internal compartment with a first pivot point, and a rotation bracket connected to the door and having a second pivot point. The first pivot point may be offset from the opening and closer to the stationary side panel than the first point when viewed along the first axis, the second pivot point may be offset from the second edge within the door by a first distance perpendicular to the door side panel and a second distance parallel to the door side panel, the second portion may at least partially define a door clearance recess, the first pivot point and the second pivot point may be rotatably connected to each other to form a rotation axis, the door may be configured to rotate about the rotation axis relative to the cabinet between a closed position and an open position, and a portion of the door side panel including the second edge may be configured to move within the door clearance recess during rotation of the door about the rotation axis.

In some embodiments, the stationary arm structure and the first pivot point may remain stationary relative to the cabinet, and the rotation bracket may remain stationary relative to the door.

In some embodiments, the first portion of the stationary arm structure may be mounted to the stationary side panel.

In some embodiments, the rotation bracket may be mounted to the door side panel.

In some embodiments, the door clearance recess may be further partially defined by the first portion, and the door clearance recess may extend around at least 90 degrees of a second axis parallel to the first axis.

In some such embodiments, the door clearance recess may be defined by a first linear surface of the second portion, a second linear surface of the first portion, and a curved surface of the first portion and/or the second portion spanning between the first linear surface and the second linear surface.

In some embodiments, in the closed position, the portion of the door side panel and the second edge may be outside the door clearance recess, and in the open position, the portion of the door side panel and the second edge may be positioned inside the door clearance recess.

In some embodiments, in the closed position, the stationary side panel and the door side panel may be substantially parallel to each other, and in the open position, the stationary side panel and the door side panel may be substantially perpendicular to each other.

In some such embodiments, the door may further include a door front surface substantially perpendicular to the door side panel, and in the open position, the stationary side panel and the door front surface may be substantially parallel to each other.

In some embodiments, the first point may be offset from the first edge by a third distance in a direction perpendicular to the first axis and parallel to the opening, the first pivot point may be offset from the opening by a fourth distance in a direction perpendicular to the opening, and offset from the first edge by a fifth distance in the first direction, and the fifth distance may be less than the third distance.

In some embodiments, the first point may be offset from the first edge by a third distance in a direction perpendicular to the first axis and parallel to the opening, and the third distance may be greater than the second distance.

In some such embodiments, the third distance may be no more than 25% larger than the second distance.

In some embodiments, the door side panel further may have a security flange with a security flange edge, the security flange may extend past the second edge by a seventh distance such that when viewed along the first axis, the security flange edge is farther from the second pivot point in a direction parallel to the door side panel than the second edge, and when in the closed position, the security flange edge may extend through the opening and into the internal compartment.

In some such embodiments, the security flange and the door side panel may define an included angle that is obtuse.

In some such embodiments, the cabinet may further have a top panel partially defining the opening and having a second security flange, and when in the closed position, the door may overlap the second security flange when viewed along the first axis.

In some embodiments, the stationary arm structure may further have a first arm, a second arm offset below the first arm in a direction parallel to the first axis, and a support member connected to and spanning between the first arm and the second arm, the first portion may have a first section of the first arm and a first section of the second arm, and the second portion may have a second section of the first arm and a second section of the second arm.

In some embodiments, when viewed along the first axis, the cabinet and the door may define a footprint, the stationary arm structure and the rotation axis may be positioned within the footprint and configured to remain stationary relative to the cabinet during movement of the door, and in the open position, the portion of the door and the second edge may be within the footprint.

In some embodiments, a secure door hinge assembly may be provided. The secure door hinge assembly may have a stationary arm structure having a first proximal end with a first mounting interface configured to be mounted to a first surface, a first distal end having a first pivot point, and a body spanning between the first proximal end and the first distal end, and extending around at least 90 degrees of a center axis to define a door clearance recess, and a rotation plate having a second proximal end with a second mounting interface configured to be mounted to a second surface separate from the first surface, and a second distal end having a second pivot point. The first pivot point and the second pivot point may be rotatably connected to each other to form a rotation axis such that the rotation plate is configured to rotate about the rotation axis with respect to the stationary arm structure, the rotation plate may be configured to rotate between a first position and a second position, in the first position, a first portion of the rotation plate may be positioned outside the door clearance recess, and in the second position, the first portion of the rotation plate may be positioned inside the door clearance recess.

In some embodiments, secure door hinge assembly may further have a door section having a door edge and connected to the rotation plate, and the door edge may be offset from the second pivot point by a first distance when viewed along the rotation axis, in the first position, the door edge and a second portion of the door section may be outside the door clearance recess, and in the second position, the door edge and the second portion of the door section may be inside the door clearance recess.

In some embodiments, secure door hinge assembly may further have a side connected to the stationary arm structure and having a side edge, and the door section may further have a security flange extending past the door edge, in the first position the door edge may be adjacent to the side edge, the security flange may extend past the side edge and overlap with the side when viewed along the rotation axis, the security flange may be outside the door clearance recess, and in the second position, the security flange may be positioned inside the door clearance recess.

Additional aspects will be set forth in the detailed description which follows, and, in part, will be apparent from the disclosure, or may be learned by practice of the disclosed embodiments and/or the claimed subject matter.

The foregoing general description and the following detailed description are illustrative and explanatory and are intended to provide further explanation of the claimed subject matter.

### BRIEF DESCRIPTION OF THE DRAWINGS

FIG. 1 is an exemplary diagram showing several EGMs networked with various gaming-related servers.

FIG. 2A is a block diagram showing various functional elements of an exemplary EGM.

FIG. 2B depicts a casino gaming environment according to one example.

FIG. 2C is a diagram that shows examples of components of a system for providing online gaming according to some aspects of the present disclosure.

FIG. 3 illustrates, in block diagram form, an implementation of a game processing architecture algorithm that implements a game processing pipeline for the play of a game in accordance with various implementations described herein.

FIG. 4 depicts an off-angle view of an electronic gaming machine according to various embodiments.

FIG. 5 depicts an off-angle view of the electronic gaming machine of FIG. 4 with the door in a partially open configuration, according to disclosed embodiments.

FIG. 6 depicts a magnified portion of the electronic gaming machine of FIG. 5, according to disclosed embodiments.

FIGS. 7A-7C depict cross-sectional top views of a simplified portion of the electronic gaming machine while the door is a closed position and in two open positions, according to disclosed embodiments.

FIG. 8 which depicts a magnified, detail view of the simplified portion of the electronic gaming machine of FIG. 7A, according to disclosed embodiments.

FIG. 9 depicts a top view of the stationary arm structure, according to disclosed embodiments.

FIG. 10 depicts an off-angle view of the stationary arm structure of FIG. 9, according to disclosed embodiments.

FIG. 11 depicts an off-angle view of the stationary arm structure of FIG. 10, according to various embodiments.

FIG. 12 depicts an off-angle view of a hinge assembly, according to various embodiments.

FIGS. 13A and 13B depict top views of the hinge assembly of FIG. 12 in various configurations, according to disclosed embodiments.

FIG. 14 depicts a cross-sectional top view of the electronic gaming machine of FIG. 4 in accordance with disclosed embodiments.

The Figures are provided for the purpose of providing examples and clarity regarding various aspects of this disclosure and are not intended to be limiting.

### DETAILED DESCRIPTION

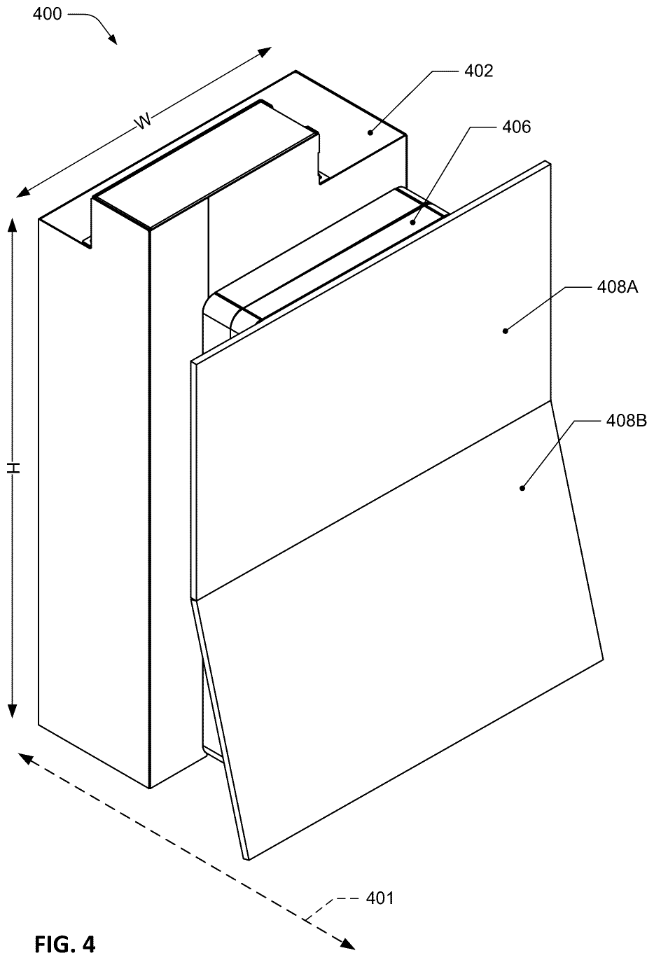

The following discussion provides overall context for electronic gaming machines, some of which may include an enclosure such as those discussed later herein starting with FIG. 4.

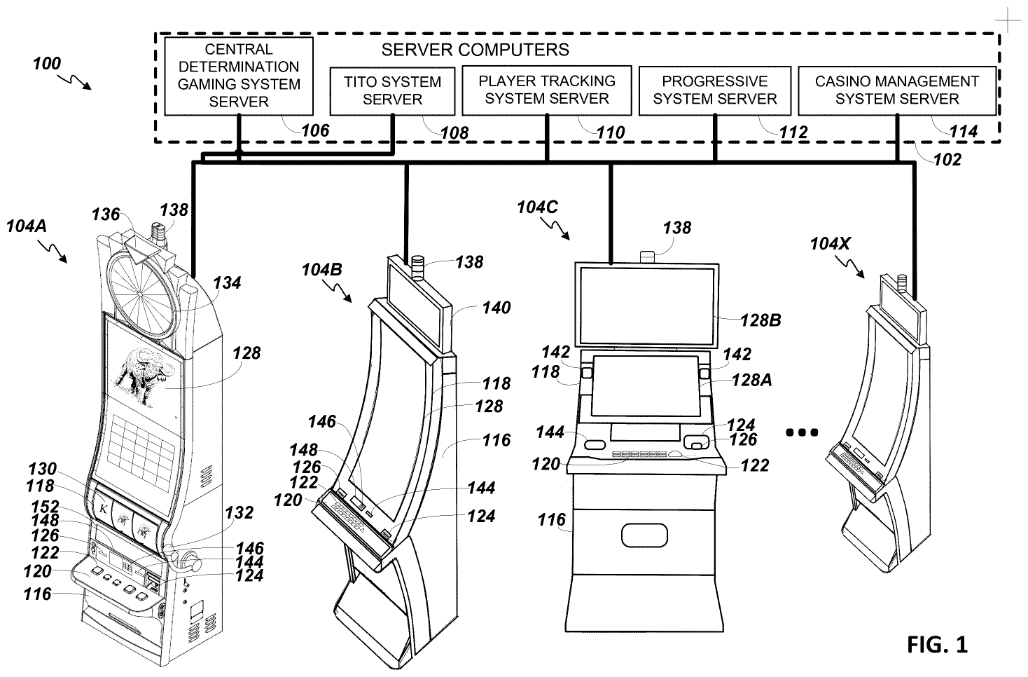

FIG. 1 illustrates several different models of EGMs which may be networked to various gaming-related servers. Shown is a system 100 in a gaming environment including one or more server computers 102 (e.g., slot servers of a casino) that are in communication, via a communications network, with one or more gaming devices 104A-104X (EGMs, slots, video poker, bingo machines, etc.) that can implement one or more aspects of the present disclosure. The gaming devices 104A-104X may alternatively be portable and/or remote gaming devices such as, but not limited to, a smart phone, a tablet, a laptop, or a game console. Gaming devices 104A-104X utilize specialized software and/or hardware to form non-generic, particular machines or apparatuses that comply with regulatory requirements regarding devices used for wagering or games of chance that provide monetary awards.

Communication between the gaming devices 104A-104X and the server computers 102, and among the gaming devices 104A-104X, may be direct or indirect using one or more communication protocols. As an example, gaming devices 104A-104X and the server computers 102 can communicate over one or more communication networks, such as over the Internet through a website maintained by a computer on a remote server or over an online data network including commercial online service providers, Internet service providers, private networks (e.g., local area networks and enterprise networks), and the like (e.g., wide area networks). The communication networks could allow gaming devices 104A-104X to communicate with one another and/or the server computers 102 using a variety of communication-based technologies, such as radio frequency (RF) (e.g., wireless fidelity (WiFi®) and Bluetooth®), cable TV, satellite links and the like.

In some implementations, server computers 102 may not be necessary and/or preferred. For example, in one or more implementations, a stand-alone gaming device such as gaming device 104A, gaming device 104B or any of the other gaming devices 104C-104X can implement one or more aspects of the present disclosure. However, it is typical to find multiple EGMs connected to networks implemented with one or more of the different server computers 102 described herein.

The server computers 102 may include a central determination gaming system server 106, a ticket-in-ticket-out (TITO) system server 108, a player tracking system server 110, a progressive system server 112, and/or a casino management system server 114. Gaming devices 104A-104X may include features to enable operation of any or all servers for use by the player and/or operator (e.g., the casino, resort, gaming establishment, tavern, pub, etc.). For example, game outcomes may be generated on a central determination gaming system server 106 and then transmitted over the network to any of a group of remote terminals or remote gaming devices 104A-104X that utilize the game outcomes and display the results to the players.

Gaming device 104A is often of a cabinet construction which may be aligned in rows or banks of similar devices for placement and operation on a casino floor. The gaming device 104A often includes a main door which provides access to the interior of the cabinet. Gaming device 104A typically includes a button area or button deck 120 accessible by a player that is configured with input switches or buttons 122, an access channel for a bill validator 124, and/or an access channel for a ticket-out printer 126.

In FIG. 1, gaming device 104A is shown as a Relm XL™ model gaming device manufactured by Aristocrat® Technologies, Inc. As shown, gaming device 104A is a reel machine having a gaming display area 118 comprising a number (typically 3 or 5) of mechanical reels 130 with various symbols displayed on them. The mechanical reels 130 are independently spun and stopped to show a set of symbols within the gaming display area 118 which may be used to determine an outcome to the game.

In many configurations, the gaming device 104A may have a main display 128 (e.g., video display monitor) mounted to, or above, the gaming display area 118. The main display 128 can be a high-resolution liquid crystal display (LCD), plasma, light emitting diode (LED), or organic light emitting diode (OLED) panel which may be flat or curved as shown, a cathode ray tube, or other conventional electronically controlled video monitor.

In some implementations, the bill validator 124 may also function as a “ticket-in” reader that allows the player to use a casino issued credit ticket to load credits onto the gaming device 104A (e.g., in a cashless ticket (“TITO”) system). In such cashless implementations, the gaming device 104A may also include a “ticket-out” printer 126 for outputting a credit ticket when a “cash out” button is pressed. Cashless TITO systems are used to generate and track unique bar-codes or other indicators printed on tickets to allow players to avoid the use of bills and coins by loading credits using a ticket reader and cashing out credits using a ticket-out printer 126 on the gaming device 104A. The gaming device 104A can have hardware meters for purposes including ensuring regulatory compliance and monitoring the player credit balance. In addition, there can be additional meters that record the total amount of money wagered on the gaming device, total amount of money deposited, total amount of money withdrawn, total amount of winnings on gaming device 104A.

In some implementations, a player tracking card reader 144, a transceiver for wireless communication with a mobile device (e.g., a player's smartphone), a keypad 146, and/or an illuminated display 148 for reading, receiving, entering, and/or displaying player tracking information is provided in gaming device 104A. In such implementations, a game controller within the gaming device 104A can communicate with the player tracking system server 110 to send and receive player tracking information.

Gaming device 104A may also include a bonus topper wheel 134. When bonus play is triggered (e.g., by a player achieving a particular outcome or set of outcomes in the primary game), bonus topper wheel 134 is operative to spin and stop with indicator arrow 136 indicating the outcome of the bonus game. Bonus topper wheel 134 is typically used to play a bonus game, but it could also be incorporated into play of the base or primary game.

A candle 138 may be mounted on the top of gaming device 104A and may be activated by a player (e.g., using a switch or one of buttons 122) to indicate to operations staff that gaming device 104A has experienced a malfunction or the player requires service. The candle 138 is also often used to indicate a jackpot has been won and to alert staff that a hand payout of an award may be needed.

There may also be one or more information panels 152 which may be a back-lit, silkscreened glass panel with lettering to indicate general game information including, for example, a game denomination (e.g., $0.25 or $1), pay lines, pay tables, and/or various game related graphics. In some implementations, the information panel(s) 152 may be implemented as an additional video display.

Gaming devices 104A have traditionally also included a handle 132 typically mounted to the side of main cabinet 116 which may be used to initiate game play.

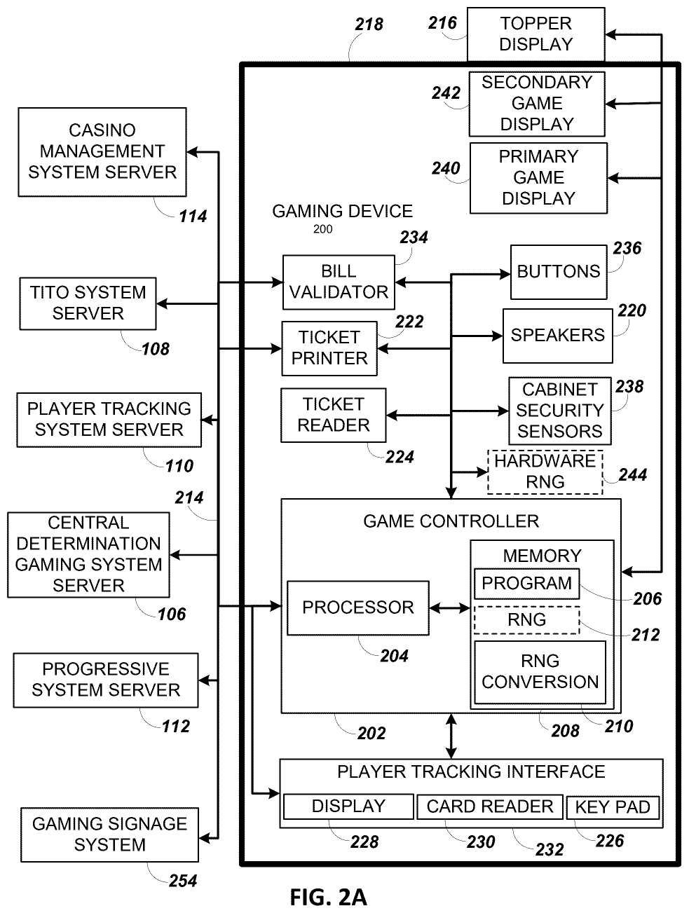

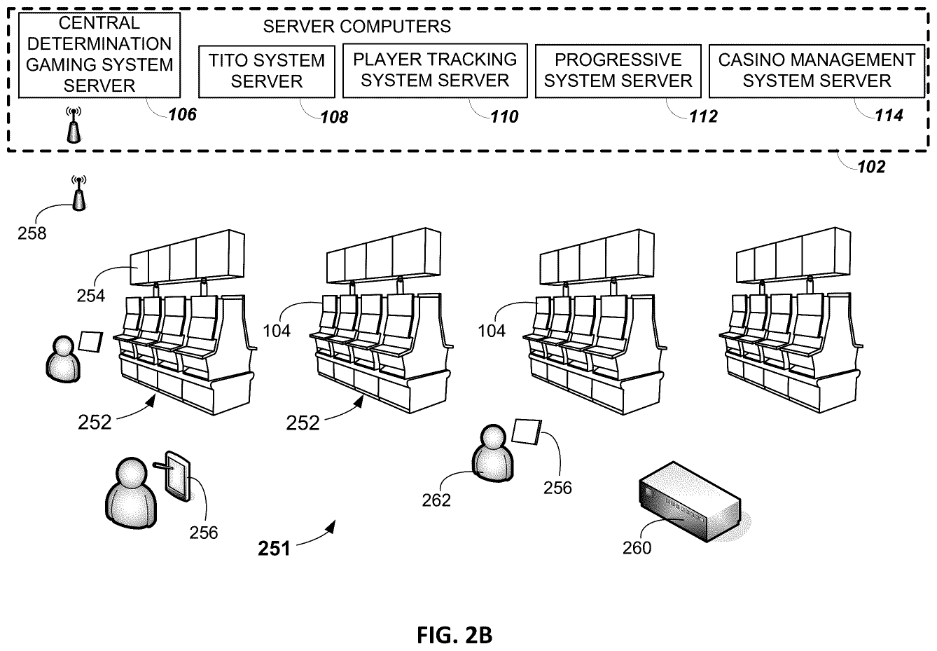

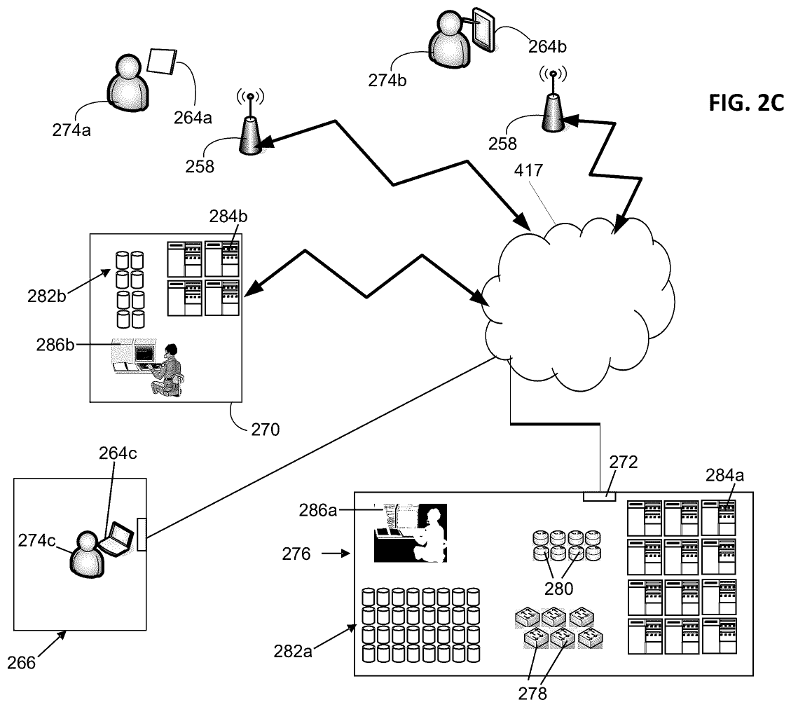

Many or all the above-described components can be controlled by circuitry (e.g., a game controller) housed inside the main cabinet 116 of the gaming device 104A, the details of which are shown in FIG. 2A.

An alternative example gaming device 104B illustrated in FIG. 1 is the Arc™ model gaming device manufactured by Aristocrat® Technologies, Inc. Note that where possible, reference numerals identifying similar features of the gaming device 104A implementation are also identified in the gaming device 104B implementation using the same reference numbers. Gaming device 104B does not include physical reels and instead shows game play functions on main display 128. An optional topper screen 140 may be used as a secondary game display for bonus play, to show game features or attraction activities while a game is not in play, or any other information or media desired by the game designer or operator. In some implementations, the optional topper screen 140 may also or alternatively be used to display progressive jackpot prizes available to a player during play of gaming device 104B.

Example gaming device 104B includes a main cabinet 116 including a main door which opens to provide access to the interior of the gaming device 104B. The main or service door is typically used by service personnel to refill the ticket-out printer 126 and collect bills and tickets inserted into the bill validator 124. The main or service door may also be accessed to reset the machine, verify and/or upgrade the software, and for general maintenance operations.

Another example gaming device 104C shown is the Helix™ model gaming device manufactured by Aristocrat® Technologies, Inc. Gaming device 104C includes a main display 128A that is in a landscape orientation. Although not illustrated by the front view provided, the main display 128A may have a curvature radius from top to bottom, or alternatively from side to side. In some implementations, main display 128A is a flat panel display. Main display 128A is typically used for primary game play while secondary display 128B is typically used for bonus game play, to show game features or attraction activities while the game is not in play or any other information or media desired by the game designer or operator. In some implementations, example gaming device 104C may also include speakers 142 to output various audio such as game sound, background music, etc.

Many different types of games, including mechanical slot games, video slot games, video poker, video black jack, video pachinko, keno, bingo, and lottery, may be provided with or implemented within the depicted gaming devices 104A-104C and other similar gaming devices. Each gaming device may also be operable to provide many different games. Games may be differentiated according to themes, sounds, graphics, type of game (e.g., slot game vs. card game vs. game with aspects of skill), denomination, number of paylines, maximum jackpot, progressive or non-progressive, bonus games, and may be deployed for operation in Class 2 or Class 3, etc.

FIG. 2A is a block diagram depicting exemplary internal electronic components of a gaming device 200 connected to various external systems. All or parts of the gaming device 200 shown could be used to implement any one of the example gaming devices 104A-X depicted in FIG. 1. As shown in FIG. 2A, gaming device 200 includes a topper display 216 or another form of a top box (e.g., a topper wheel, a topper screen, etc.) that sits above cabinet 218. Cabinet 218 or topper display 216 may also house a number of other components which may be used to add features to a game being played on gaming device 200, including speakers 220, a ticket printer 222 which prints bar-coded tickets or other media or mechanisms for storing or indicating a player's credit value, a ticket reader 224 which reads bar-coded tickets or other media or mechanisms for storing or indicating a player's credit value, and a player tracking interface 232. Player tracking interface 232 may include a keypad 226 for entering information, a player tracking display 228 for displaying information (e.g., an illuminated or video display), a card reader 230 for receiving data and/or communicating information to and from media or a device such as a smart phone enabling player tracking. FIG. 2 also depicts utilizing a ticket printer 222 to print tickets for a TITO system server 108. Gaming device 200 may further include a bill validator 234, player-input buttons 236 for player input, cabinet security sensors 238 to detect unauthorized opening of the cabinet 218, a primary game display 240, and a secondary game display 242, each coupled to and operable under the control of game controller 202.

The games available for play on the gaming device 200 are controlled by a game controller 202 that includes one or more processors 204. Processor 204 represents a general-purpose processor, a specialized processor intended to perform certain functional tasks, or a combination thereof. As an example, processor 204 can be a central processing unit (CPU) that has one or more multi-core processing units and memory mediums (e.g., cache memory) that function as buffers and/or temporary storage for data. Alternatively, processor 204 can be a specialized processor, such as an application specific integrated circuit (ASIC), graphics processing unit (GPU), field-programmable gate array (FPGA), digital signal processor (DSP), or another type of hardware accelerator. In another example, processor 204 is a system on chip (SoC) that combines and integrates one or more general-purpose processors and/or one or more specialized processors. Although FIG. 2A illustrates that game controller 202 includes a single processor 204, game controller 202 is not limited to this representation and instead can include multiple processors 204 (e.g., two or more processors).

FIG. 2A illustrates that processor 204 is operatively coupled to memory 208. Memory 208 is defined herein as including volatile and nonvolatile memory and other types of non-transitory data storage components. Volatile memory is memory that do not retain data values upon loss of power. Nonvolatile memory is memory that do retain data upon a loss of power. Examples of memory 208 include random access memory (RAM), read-only memory (ROM), hard disk drives, solid-state drives, universal serial bus (USB) flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, examples of RAM include static random access memory (SRAM), dynamic random access memory (DRAM), magnetic random access memory (MRAM), and other such devices. Examples of ROM include a programmable read-only memory (PROM), an erasable programmable read-only memory (EPROM), an electrically erasable programmable read-only memory (EEPROM), or other like memory device. Even though FIG. 2A illustrates that game controller 202 includes a single memory 208, game controller 202 could include multiple memories 208 for storing program instructions and/or data.

Memory 208 can store one or more game programs 206 that provide program instructions and/or data for carrying out various implementations (e.g., game mechanics) described herein. Stated another way, game program 206 represents an executable program stored in any portion or component of memory 208. In one or more implementations, game program 206 is embodied in the form of source code that includes human-readable statements written in a programming language or machine code that contains numerical instructions recognizable by a suitable execution system, such as a processor 204 in a game controller or other system. Examples of executable programs include: (1) a compiled program that can be translated into machine code in a format that can be loaded into a random access portion of memory 208 and run by processor 204; (2) source code that may be expressed in proper format such as object code that is capable of being loaded into a random access portion of memory 208 and executed by processor 204; and (3) source code that may be interpreted by another executable program to generate instructions in a random access portion of memory 208 to be executed by processor 204.

Alternatively, game programs 206 can be set up to generate one or more game instances based on instructions and/or data that gaming device 200 exchanges with one or more remote gaming devices, such as a central determination gaming system server 106 (not shown in FIG. 2A but shown in FIG. 1). For purpose of this disclosure, the term “game instance” refers to a play or a round of a game that gaming device 200 presents (e.g., via a user interface (UI)) to a player. The game instance is communicated to gaming device 200 via the network 214 and then displayed on gaming device 200. For example, gaming device 200 may execute game program 206 as video streaming software that allows the game to be displayed on gaming device 200. When a game is stored on gaming device 200, it may be loaded from memory 208 (e.g., from a read only memory (ROM)) or from the central determination gaming system server 106 to memory 208.

Gaming devices, such as gaming device 200, are highly regulated to ensure fairness and, in many cases, gaming device 200 is operable to award monetary awards (e.g., typically dispensed in the form of a redeemable voucher). Therefore, to satisfy security and regulatory requirements in a gaming environment, hardware and software architectures are implemented in gaming devices 200 that differ significantly from those of general-purpose computers. Adapting general purpose computers to function as gaming devices 200 is not simple or straightforward because of: (1) the regulatory requirements for gaming devices 200, (2) the harsh environment in which gaming devices 200 operate, (3) security requirements, (4) fault tolerance requirements, and (5) the requirement for additional special purpose componentry enabling functionality of an EGM. These differences require substantial engineering effort with respect to game design implementation, game mechanics, hardware components, and software.

One regulatory requirement for games running on gaming device 200 generally involves complying with a certain level of randomness. Typically, gaming jurisdictions mandate that gaming devices 200 satisfy a minimum level of randomness without specifying how a gaming device 200 should achieve this level of randomness. To comply, FIG. 2A illustrates that gaming device 200 could include an RNG 212 that utilizes hardware and/or software to generate RNG outcomes that lack any pattern. The RNG operations are often specialized and non-generic in order to comply with regulatory and gaming requirements. For example, in a slot game, game program 206 can initiate multiple RNG calls to RNG 212 to generate RNG outcomes, where each RNG call and RNG outcome corresponds to an outcome for a reel. In another example, gaming device 200 can be a Class II gaming device where RNG 212 generates RNG outcomes for creating Bingo cards. In one or more implementations, RNG 212 could be one of a set of RNGs operating on gaming device 200. More generally, an output of the RNG 212 can be the basis on which game outcomes are determined by the game controller 202. Game developers could vary the degree of true randomness for each RNG (e.g., pseudorandom) and utilize specific RNGs depending on game requirements. The output of the RNG 212 can include a random number or pseudorandom number (either is generally referred to as a “random number”).

In FIG. 2A, RNG 212 and hardware RNG 244 are shown in dashed lines to illustrate that RNG 212, hardware RNG 244, or both can be included in gaming device 200. In one implementation, instead of including RNG 212, gaming device 200 could include a hardware RNG 244 that generates RNG outcomes. Analogous to RNG 212, hardware RNG 244 performs specialized and non-generic operations in order to comply with regulatory and gaming requirements. For example, because of regulation requirements, hardware RNG 244 could be a random number generator that securely produces random numbers for cryptography use. The gaming device 200 then uses the secure random numbers to generate game outcomes for one or more game features. In another implementation, the gaming device 200 could include both hardware RNG 244 and RNG 212. RNG 212 may utilize the RNG outcomes from hardware RNG 244 as one of many sources of entropy for generating secure random numbers for the game features.

Another regulatory requirement for running games on gaming device 200 includes ensuring a certain level of RTP. Similar to the randomness requirement discussed above, numerous gaming jurisdictions also mandate that gaming device 200 provides a minimum level of RTP (e.g., RTP of at least 75%). A game can use one or more lookup tables (also called weighted tables) as part of a technical solution that satisfies regulatory requirements for randomness and RTP. In particular, a lookup table can integrate game features (e.g., trigger events for special modes or bonus games; newly introduced game elements such as extra reels, new symbols, or new cards; stop positions for dynamic game elements such as spinning reels, spinning wheels, or shifting reels; or card selections from a deck) with random numbers generated by one or more RNGs, so as to achieve a given level of volatility for a target level of RTP. (In general, volatility refers to the frequency or probability of an event such as a special mode, payout, etc. For example, for a target level of RTP, a higher-volatility game may have a lower payout most of the time with an occasional bonus having a very high payout, while a lower-volatility game has a steadier payout with more frequent bonuses of smaller amounts.) Configuring a lookup table can involve engineering decisions with respect to how RNG outcomes are mapped to game outcomes for a given game feature, while still satisfying regulatory requirements for RTP. Configuring a lookup table can also involve engineering decisions about whether different game features are combined in a given entry of the lookup table or split between different entries (for the respective game features), while still satisfying regulatory requirements for RTP and allowing for varying levels of game volatility.

FIG. 2A illustrates that gaming device 200 includes an RNG conversion engine 210 that translates the RNG outcome from RNG 212 to a game outcome presented to a player. To meet a designated RTP, a game developer can set up the RNG conversion engine 210 to utilize one or more lookup tables to translate the RNG outcome to a symbol element, stop position on a reel strip layout, and/or randomly chosen aspect of a game feature. As an example, the lookup tables can regulate a prize payout amount for each RNG outcome and how often the gaming device 200 pays out the prize payout amounts. The RNG conversion engine 210 could utilize one lookup table to map the RNG outcome to a game outcome displayed to a player and a second lookup table as a pay table for determining the prize payout amount for each game outcome. The mapping between the RNG outcome to the game outcome controls the frequency in hitting certain prize payout amounts.

FIG. 2A also depicts that gaming device 200 is connected over network 214 to player tracking system server 110. Player tracking system server 110 may be, for example, an OASIS® system manufactured by Aristocrat® Technologies, Inc. Player tracking system server 110 is used to track play (e.g., amount wagered, games played, time of play and/or other quantitative or qualitative measures) for individual players so that an operator may reward players in a loyalty program. The player may use the player tracking interface 232 to access his/her account information, activate free play, and/or request various information. Player tracking or loyalty programs seek to reward players for their play and help build brand loyalty to the gaming establishment. The rewards typically correspond to the player's level of patronage (e.g., to the player's playing frequency and/or total amount of game plays at a given casino). Player tracking rewards may be complimentary and/or discounted meals, lodging, entertainment and/or additional play. Player tracking information may be combined with other information that is now readily obtainable by a casino management system.

When a player wishes to play the gaming device 200, he/she can insert cash or a ticket voucher through a coin acceptor (not shown) or bill validator 234 to establish a credit balance on the gaming device. The credit balance is used by the player to place wagers on instances of the game and to receive credit awards based on the outcome of winning instances. The credit balance is decreased by the amount of each wager and increased upon a win. The player can add additional credits to the balance at any time. The player may also optionally insert a loyalty club card into the card reader 230. During the game, the player views with one or more UIs, the game outcome on one or more of the primary game display 240 and secondary game display 242. Other game and prize information may also be displayed.

For each game instance, a player may make selections, which may affect play of the game. For example, the player may vary the total amount wagered by selecting the amount bet per line and the number of lines played. In many games, the player is asked to initiate or select options during course of game play (such as spinning a wheel to begin a bonus round or select various items during a feature game). The player may make these selections using the player-input buttons 236, the primary game display 240 which may be a touch screen, or using some other device which enables a player to input information into the gaming device 200.

During certain game events, the gaming device 200 may display visual and auditory effects that can be perceived by the player. These effects add to the excitement of a game, which makes a player more likely to enjoy the playing experience. Auditory effects include various sounds that are projected by the speakers 220. Visual effects include flashing lights, strobing lights or other patterns displayed from lights on the gaming device 200 or from lights behind the information panel 152 (FIG. 1).

When the player is done, he/she cashes out the credit balance (typically by pressing a cash out button to receive a ticket from the ticket printer 222). The ticket may be “cashed-in” for money or inserted into another machine to establish a credit balance for play.

Additionally, or alternatively, gaming devices 104A-104X and 200 can include or be coupled to one or more wireless transmitters, receivers, and/or transceivers (not shown in FIGS. 1 and 2A) that communicate (e.g., Bluetooth® or other near-field communication technology) with one or more mobile devices to perform a variety of wireless operations in a casino environment. Examples of wireless operations in a casino environment include detecting the presence of mobile devices, performing credit, points, comps, or other marketing or hard currency transfers, establishing wagering sessions, and/or providing a personalized casino-based experience using a mobile application. In one implementation, to perform these wireless operations, a wireless transmitter or transceiver initiates a secure wireless connection between a gaming device 104A-104X and 200 and a mobile device. After establishing a secure wireless connection between the gaming device 104A-104X and 200 and the mobile device, the wireless transmitter or transceiver does not send and/or receive application data to and/or from the mobile device. Rather, the mobile device communicates with gaming devices 104A-104X and 200 using another wireless connection (e.g., WiFi® or cellular network). In another implementation, a wireless transceiver establishes a secure connection to directly communicate with the mobile device. The mobile device and gaming device 104A-104X and 200 sends and receives data utilizing the wireless transceiver instead of utilizing an external network. For example, the mobile device would perform digital wallet transactions by directly communicating with the wireless transceiver. In one or more implementations, a wireless transmitter could broadcast data received by one or more mobile devices without establishing a pairing connection with the mobile devices.

Although FIGS. 1 and 2A illustrate specific implementations of a gaming device (e.g., gaming devices 104A-104X and 200), the disclosure is not limited to those implementations shown in FIGS. 1 and 2. For example, not all gaming devices suitable for implementing implementations of the present disclosure necessarily include top wheels, top boxes, information panels, cashless ticket systems, and/or player tracking systems. Further, some suitable gaming devices have only a single game display that includes only a mechanical set of reels and/or a video display, while others are designed for bar counters or tabletops and have displays that face upwards. Gaming devices 104A-104X and 200 may also include other processors that are not separately shown. Using FIG. 2A as an example, gaming device 200 could include display controllers (not shown in FIG. 2A) configured to receive video input signals or instructions to display images on game displays 240 and 242. Alternatively, such display controllers may be integrated into the game controller 202. The use and discussion of FIGS. 1 and 2 are examples to facilitate ease of description and explanation.

FIG. 2B depicts a casino gaming environment according to one example. In this example, the casino 251 includes banks 252 of EGMs 104. In this example, each bank 252 of EGMs 104 includes a corresponding gaming signage system 254 (also shown in FIG. 2A). According to this implementation, the casino 251 also includes mobile gaming devices 256, which are also configured to present wagering games in this example. The mobile gaming devices 256 may, for example, include tablet devices, cellular phones, smart phones and/or other handheld devices. In this example, the mobile gaming devices 256 are configured for communication with one or more other devices in the casino 251, including but not limited to one or more of the server computers 102, via wireless access points 258.

According to some examples, the mobile gaming devices 256 may be configured for stand-alone determination of game outcomes. However, in some alternative implementations the mobile gaming devices 256 may be configured to receive game outcomes from another device, such as the central determination gaming system server 106, one of the EGMs 104, etc.

Some mobile gaming devices 256 may be configured to accept monetary credits from a credit or debit card, via a wireless interface (e.g., via a wireless payment app), via tickets, via a patron casino account, etc. However, some mobile gaming devices 256 may not be configured to accept monetary credits via a credit or debit card. Some mobile gaming devices 256 may include a ticket reader and/or a ticket printer whereas some mobile gaming devices 256 may not, depending on the particular implementation.

In some implementations, the casino 251 may include one or more kiosks 260 that are configured to facilitate monetary transactions involving the mobile gaming devices 256, which may include cash out and/or cash in transactions. The kiosks 260 may be configured for wired and/or wireless communication with the mobile gaming devices 256. The kiosks 260 may be configured to accept monetary credits from casino patrons 262 and/or to dispense monetary credits to casino patrons 262 via cash, a credit or debit card, via a wireless interface (e.g., via a wireless payment app), via tickets, etc. According to some examples, the kiosks 260 may be configured to accept monetary credits from a casino patron and to provide a corresponding amount of monetary credits to a mobile gaming device 256 for wagering purposes, e.g., via a wireless link such as a near-field communications link. In some such examples, when a casino patron 262 is ready to cash out, the casino patron 262 may select a cash out option provided by a mobile gaming device 256, which may include a real button or a virtual button (e.g., a button provided via a graphical user interface) in some instances. In some such examples, the mobile gaming device 256 may send a “cash out” signal to a kiosk 260 via a wireless link in response to receiving a “cash out” indication from a casino patron. The kiosk 260 may provide monetary credits to the casino patron 262 corresponding to the “cash out” signal, which may be in the form of cash, a credit ticket, a credit transmitted to a financial account corresponding to the casino patron, etc.

In some implementations, a cash-in process and/or a cash-out process may be facilitated by the TITO system server 108. For example, the TITO system server 108 may control, or at least authorize, ticket-in and ticket-out transactions that involve a mobile gaming device 256 and/or a kiosk 260.

Some mobile gaming devices 256 may be configured for receiving and/or transmitting player loyalty information. For example, some mobile gaming devices 256 may be configured for wireless communication with the player tracking system server 110. Some mobile gaming devices 256 may be configured for receiving and/or transmitting player loyalty information via wireless communication with a patron's player loyalty card, a patron's smartphone, etc.

According to some implementations, a mobile gaming device 256 may be configured to provide safeguards that prevent the mobile gaming device 256 from being used by an unauthorized person. For example, some mobile gaming devices 256 may include one or more biometric sensors and may be configured to receive input via the biometric sensor(s) to verify the identity of an authorized patron. Some mobile gaming devices 256 may be configured to function only within a predetermined or configurable area, such as a casino gaming area.

FIG. 2C is a diagram that shows examples of components of a system for providing online gaming according to some aspects of the present disclosure. As with other figures presented in this disclosure, the numbers, types and arrangements of gaming devices shown in FIG. 2C are merely shown by way of example. In this example, various gaming devices, including but not limited to end user devices (EUDs) 264a, 264b and 264c are capable of communication via one or more networks 417. The networks 417 may, for example, include one or more cellular telephone networks, the Internet, etc. In this example, the EUDs 264a and 264b are mobile devices: according to this example the EUD 264a is a tablet device and the EUD 264b is a smart phone. In this implementation, the EUD 264c is a laptop computer that is located within a residence 266 at the time depicted in FIG. 2C. Accordingly, in this example the hardware of EUDs is not specifically configured for online gaming, although each EUD is configured with software for online gaming. For example, each EUD may be configured with a web browser. Other implementations may include other types of EUD, some of which may be specifically configured for online gaming.

In this example, a gaming data center 276 includes various devices that are configured to provide online wagering games via the networks 417. The gaming data center 276 may, for example, be a remote gaming server (RGS) or similar system in some implementations. The gaming data center 276 is capable of communication with the networks 417 via the gateway 272. In this example, switches 278 and routers 280 are configured to provide network connectivity for devices of the gaming data center 276, including storage devices 282a, servers 284a and one or more workstations 286b. The servers 284a may, for example, be configured to provide access to a library of games for online game play. In some examples, code for executing at least some of the games may initially be stored on one or more of the storage devices 282a. The code may be subsequently loaded onto a server 284a after selection by a player via an EUD and communication of that selection from the EUD via the networks 417. The server 284a onto which code for the selected game has been loaded may provide the game according to selections made by a player and indicated via the player's EUD. In other examples, code for executing at least some of the games may initially be stored on one or more of the servers 284a. Although only one gaming data center 276 is shown in FIG. 2C, some implementations may include multiple gaming data centers 276.

In this example, a financial institution data center 270 is also configured for communication via the networks 417. Here, the financial institution data center 270 includes servers 284b, storage devices 282b, and one or more workstations 286b. According to this example, the financial institution data center 270 is configured to maintain financial accounts, such as checking accounts, savings accounts, loan accounts, etc. In some implementations one or more of the authorized users 274a-274c may maintain at least one financial account with the financial institution that is serviced via the financial institution data center 270.

According to some implementations, the gaming data center 276 may be configured to provide online wagering games in which money may be won or lost. According to some such implementations, one or more of the servers 284a may be configured to monitor player credit balances, which may be expressed in game credits, in currency units, or in any other appropriate manner. In some implementations, the server(s) 284a may be configured to obtain financial credits from and/or provide financial credits to one or more financial institutions, according to a player's “cash in” selections, wagering game results and a player's “cash out” instructions. According to some such implementations, the server(s) 284a may be configured to electronically credit or debit the account of a player that is maintained by a financial institution, e.g., an account that is maintained via the financial institution data center 270. The server(s) 284a may, in some examples, be configured to maintain an audit record of such transactions.

In some alternative implementations, the gaming data center 276 may be configured to provide online wagering games for which credits may not be exchanged for cash or the equivalent. In some such examples, players may purchase game credits for online game play, but may not “cash out” for monetary credit after a gaming session. Moreover, although the financial institution data center 270 and the gaming data center 276 include their own servers and storage devices in this example, in some examples the financial institution data center 270 and/or the gaming data center 276 may use offsite “cloud-based” servers and/or storage devices. In some alternative examples, the financial institution data center 270 and/or the gaming data center 276 may rely entirely on cloud-based servers.

One or more types of devices in the gaming data center 276 (or elsewhere) may be capable of executing middleware, e.g., for data management and/or device communication. Authentication information, player tracking information, etc., including but not limited to information obtained by EUDs 264 and/or other information regarding authorized users of EUDs 264 (including but not limited to the authorized users 274a-274c), may be stored on storage devices 282 and/or servers 284. Other game-related information and/or software, such as information and/or software relating to leaderboards, players currently playing a game, game themes, game-related promotions, game competitions, etc., also may be stored on storage devices 282 and/or servers 284. In some implementations, some such game-related software may be available as “apps” and may be downloadable (e.g., from the gaming data center 276) by authorized users.

In some examples, authorized users and/or entities (such as representatives of gaming regulatory authorities) may obtain gaming-related information via the gaming data center 276. One or more other devices (such EUDs 264 or devices of the gaming data center 276) may act as intermediaries for such data feeds. Such devices may, for example, be capable of applying data filtering algorithms, executing data summary and/or analysis software, etc. In some implementations, data filtering, summary and/or analysis software may be available as “apps” and downloadable by authorized users.

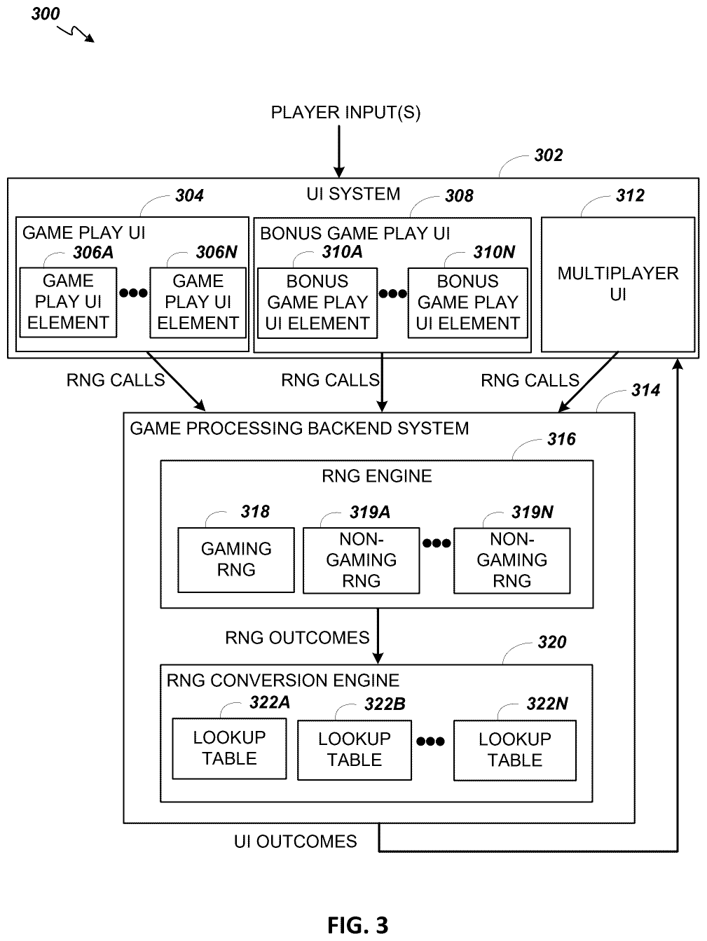

FIG. 3 illustrates, in block diagram form, an implementation of a game processing architecture 300 that implements a game processing pipeline for the play of a game in accordance with various implementations described herein. As shown in FIG. 3, the gaming processing pipeline starts with having a UI system 302 receive one or more player inputs for the game instance. Based on the player input(s), the UI system 302 generates and sends one or more RNG calls to a game processing backend system 314. Game processing backend system 314 then processes the RNG calls with RNG engine 316 to generate one or more RNG outcomes. The RNG outcomes are then sent to the RNG conversion engine 320 to generate one or more game outcomes for the UI system 302 to display to a player. The game processing architecture 300 can implement the game processing pipeline using a gaming device, such as gaming devices 104A-104X and 200 shown in FIGS. 1 and 2, respectively. Alternatively, portions of the gaming processing architecture 300 can implement the game processing pipeline using a gaming device and one or more remote gaming devices, such as central determination gaming system server 106 shown in FIG. 1.

The UI system 302 includes one or more UIs that a player can interact with. The UI system 302 could include one or more game play UIs 304, one or more bonus game play UIs 308, and one or more multiplayer UIs 312, where each UI type includes one or more mechanical UIs and/or graphical UIs (GUIs). In other words, game play UI 304, bonus game play UI 308, and the multiplayer UI 312 may utilize a variety of UI elements, such as mechanical UI elements (e.g., physical “spin” button or mechanical reels) and/or GUI elements (e.g., virtual reels shown on a video display or a virtual button deck) to receive player inputs and/or present game play to a player. Using FIG. 3 as an example, the different UI elements are shown as game play UI elements 306A-306N and bonus game play UI elements 310A-310N.

The game play UI 304 represents a UI that a player typically interfaces with for a base game. During a game instance of a base game, the game play UI elements 306A-306N (e.g., GUI elements depicting one or more virtual reels) are shown and/or made available to a user. In a subsequent game instance, the UI system 302 could transition out of the base game to one or more bonus games. The bonus game play UI 308 represents a UI that utilizes bonus game play UI elements 310A-310N for a player to interact with and/or view during a bonus game. In one or more implementations, at least some of the game play UI element 306A-306N are similar to the bonus game play UI elements 310A-310N. In other implementations, the game play UI element 306A-306N can differ from the bonus game play UI elements 310A-310N.

FIG. 3 also illustrates that UI system 302 could include a multiplayer UI 312 purposed for game play that differs or is separate from the typical base game. For example, multiplayer UI 312 could be set up to receive player inputs and/or presents game play information relating to a tournament mode. When a gaming device transitions from a primary game mode that presents the base game to a tournament mode, a single gaming device is linked and synchronized to other gaming devices to generate a tournament outcome. For example, multiple RNG engines 316 corresponding to each gaming device could be collectively linked to determine a tournament outcome. To enhance a player's gaming experience, tournament mode can modify and synchronize sound, music, reel spin speed, and/or other operations of the gaming devices according to the tournament game play. After tournament game play ends, operators can switch back the gaming device from tournament mode to a primary game mode to present the base game. Although FIG. 3 does not explicitly depict that multiplayer UI 312 includes UI elements, multiplayer UI 312 could also include one or more multiplayer UI elements.

Based on the player inputs, the UI system 302 could generate RNG calls to a game processing backend system 314. As an example, the UI system 302 could use one or more application programming interfaces (APIs) to generate the RNG calls. To process the RNG calls, the RNG engine 316 could utilize gaming RNG 318 and/or non-gaming RNGs 319A-319N. Gaming RNG 318 could corresponds to RNG 212 or hardware RNG 244 shown in FIG. 2A. As previously discussed with reference to FIG. 2A, gaming RNG 318 often performs specialized and non-generic operations that comply with regulatory and/or game requirements. For example, because of regulation requirements, gaming RNG 318 could correspond to RNG 212 by being a cryptographic RNG or pseudorandom number generator (PRNG) (e.g., Fortuna PRNG) that securely produces random numbers for one or more game features. To securely generate random numbers, gaming RNG 318 could collect random data from various sources of entropy, such as from an operating system (OS) and/or a hardware RNG (e.g., hardware RNG 244 shown in FIG. 2A). Alternatively, non-gaming RNGs 319A-319N may not be cryptographically secure and/or be computationally less expensive. Non-gaming RNGs 319A-319N can, thus, be used to generate outcomes for non-gaming purposes. As an example, non-gaming RNGs 319A-319N can generate random numbers for generating random messages that appear on the gaming device.

The RNG conversion engine 320 processes each RNG outcome from RNG engine 316 and converts the RNG outcome to a UI outcome that is feedback to the UI system 302. With reference to FIG. 2A, RNG conversion engine 320 corresponds to RNG conversion engine 210 used for game play. As previously described, RNG conversion engine 320 translates the RNG outcome from the RNG 212 to a game outcome presented to a player. RNG conversion engine 320 utilizes one or more lookup tables 322A-322N to regulate a prize payout amount for each RNG outcome and how often the gaming device pays out the derived prize payout amounts. In one example, the RNG conversion engine 320 could utilize one lookup table to map the RNG outcome to a game outcome displayed to a player and a second lookup table as a pay table for determining the prize payout amount for each game outcome. In this example, the mapping between the RNG outcome and the game outcome controls the frequency in hitting certain prize payout amounts. Different lookup tables could be utilized depending on the different game modes, for example, a base game versus a bonus game.

After generating the UI outcome, the game processing backend system 314 sends the UI outcome to the UI system 302. Examples of UI outcomes are symbols to display on a video reel or reel stops for a mechanical reel. In one example, if the UI outcome is for a base game, the UI system 302 updates one or more game play UI elements 306A-306N, such as symbols, for the game play UI 304. In another example, if the UI outcome is for a bonus game, the UI system could update one or more bonus game play UI elements 310A-310N (e.g., symbols) for the bonus game play UI 308. In response to updating the appropriate UI, the player may subsequently provide additional player inputs to initiate a subsequent game instance that progresses through the game processing pipeline.

Electronic gaming machines such as those discussed above may have cabinets with access panels, doors, or slide-out trays, or separate enclosures (e.g., a bill validator cage) within the cabinet each having its own access panel, door, or slide-out tray. Some electronic gaming machines (EGMs) have a cabinet with a door to which one or more display devices are mounted and these doors may swing open to provide access to the backside of the display devices as well as an internal compartment of the cabinet. While it may be advantageous to mount one or more display devices to a door of the cabinet, such configuration presents numerous challenges. For example, many EGMs are placed side-by-side in locations, such as casinos, that have standardized or preset locations for each EGM which presents size, movement, and clearance constraints for the EGMs. Further, many EGMs are subject to various operational requirements, such as the ability to open a service or access door at least 90 degrees. Other operational requirements may also include security surfaces around the opening of the door to secure the internal compartment and prevent unwanted tampering, access, or opening of the door. Individually or together, these location and operational constraints present unique challenges for designing doors on EGMs. Further still, some EGMs have cabinets that are off-center from their footprint, thereby providing off-center hinge points for doors. For access doors having one or more display devices mounted thereto, the weight of such devices presents additional challenges for providing properly functioning doors.

Provided herein are new and novel hinge assemblies for doors of electronic gaming machines. Some embodiments provide an EGM with a cabinet having an internal compartment, an opening, and a door providing access to the internal compartment of the cabinet through the opening. The door is rotatably connected to the cabinet by a hinge assembly with a stationary arm structure mounted to the cabinet and that provides a pivot point, or rotational axis, for the door to rotate about. The pivot point for the door is offset from the door edge such that when the door rotates to open, a portion of the door moves inwards towards the stationary arm structure. To accommodate this portion of the door, the stationary arm structure has a recess, such as a door clearance recess, where the portion of the door can move into as the door rotates. In some embodiments, the hinge assembly has a rotation bracket connected to the door and that provides a hinge point for the door. The rotation bracket is rotatably connected to the stationary arm structure such that when the door rotates, the stationary arm structure does not move, and the rotation bracket and door rotate with respect to the stationary cabinet and stationary arm structure.

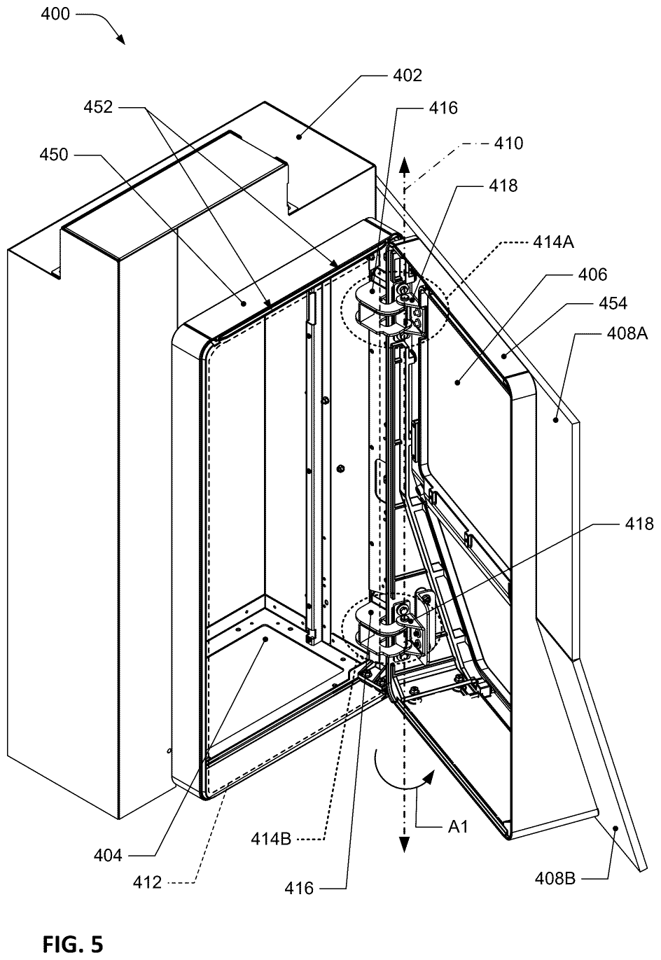

FIG. 4 depicts an off-angle view of an electronic gaming machine according to various embodiments. The electronic gaming machine (EGM) 400 has a cabinet 402 having a height H and a width W and defining an internal compartment (not visible here) which may be considered an area inside of the cabinet 402. The cabinet 402 also has a door 406 rotatably connected to the cabinet 402 and having a first display 408A and a second display 408B connected to, or mounted on, the door 406. The door 406 is configured to rotate about a vertical rotation axis, with respect to the floor on which the EGM 400 is directly or indirectly positioned, to open outwards as illustrated in FIG. 5.

FIG. 5 depicts an off-angle view of the electronic gaming machine of FIG. 4 with the door in a partially open configuration. The door 406 has been rotated outwards about the rotation axis 410 and the internal compartment 404 defined by the cabinet 402 is visible. The cabinet 402 also has an opening 412 (identified by a dashed rectangle) through which access can be made into the internal compartment 404 for various reasons such as maintenance, service, removing components like a cashbox or electronics, etc. During normal operations of EGM 400, the opening 412 is covered by the door 406 and access is prevented to the internal compartment 404. To provide and restrict access to the internal compartment 404, the door 406 is configured to rotate about the rotation axis 410 between a closed position and one or more open positions. FIG. 5 depicts the door 406 in a partially open position and FIG. 4 depicts the EGM 400 with the door 406 in the closed position. As illustrated in these Figures, when the door 406 is in the open position, the opening 412 is at least partially uncovered and access to the internal compartment 404 is provided through the opening 412; while in the closed position, the door 406 covers the opening 412 of the cabinet 402 and the internal compartment 404 is not accessible through the opening 412.

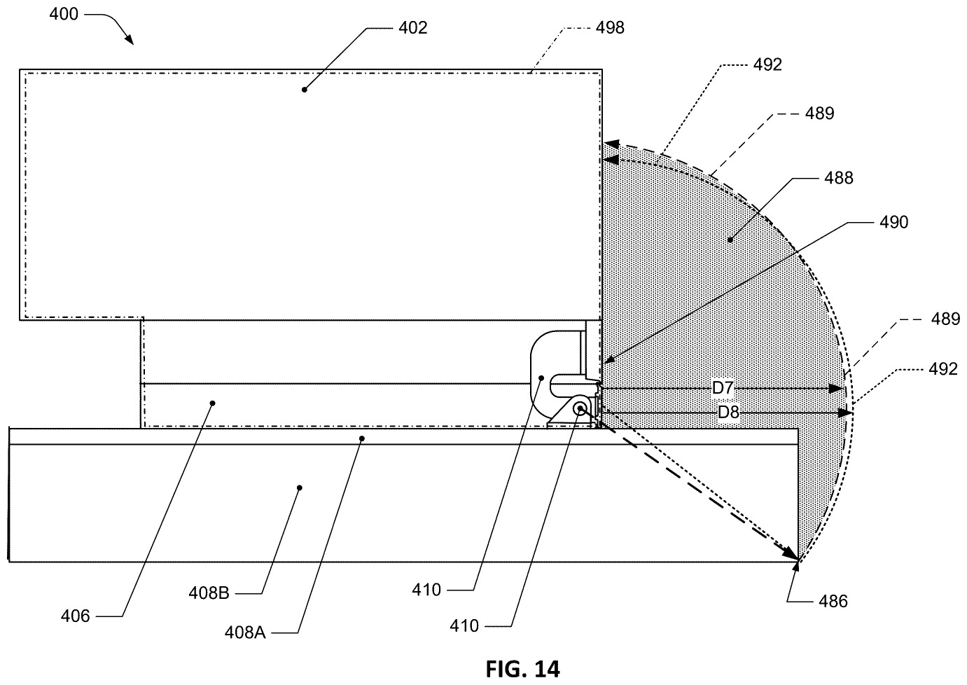

As mentioned above, due to various constraints, such as clearance between adjacent EGMs, the door 406 of the EGM 400 is unable to use conventional hinges because doing so causes the door 406 and its displays to rotate too far outwards and contact adjacent EGMs. For example, some EGMs have hinges that provide a rotation axis that coincides with the exterior surface of the machine, such as a piano-style hinge. Such hinges cause the door to rotate too far outwards from the EGM. See FIG. 14 and the corresponding discussion below. Accordingly, the EGM 400 uses a hinge assembly 414 having a stationary arm structure 416 connected to the cabinet 402 and a rotation bracket 418 connected to the door 406. Here in FIG. 5, the EGM 400 has two hinge assemblies 414A and 414B that may be the same or identical. The features of the hinge assembly 414 are provided below.

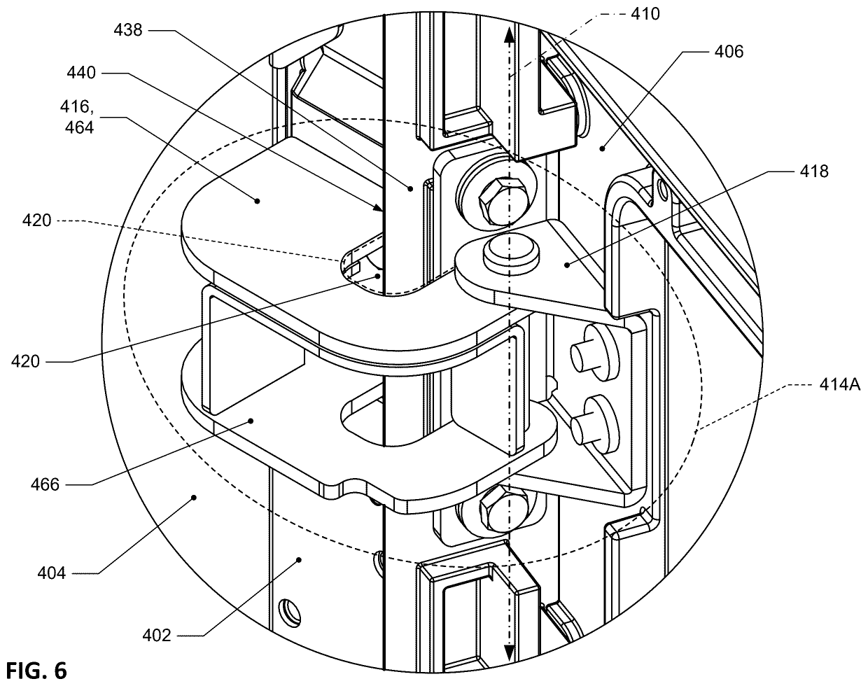

The upper hinge assembly 414A is more clearly visible in FIG. 6 which depicts a magnified portion of the electronic gaming machine of FIG. 5. Here, the stationary arm structure 416 connected to the cabinet 402 and the rotation bracket 418 is connected to the door 406. The stationary arm structure 416 is rotatably connected to the rotation bracket 418 to form the rotation axis 410. The rotation bracket 418, along with the door 406 connected to the rotation bracket 418, is configured to rotate about the rotation axis 410 relative to the stationary arm structure 416 and the cabinet 402. During such rotation and movement of the rotation bracket 418, no other components of the hinge assembly 414 move. For example, the stationary arm structure 416 has no moving parts and remains stationary while the rotation bracket 418 moves with respect to the stationary arm structure 416. As shown and discussed in more detail below, the rotation axis 410 is offset away from the opening 412 and the internal compartment 404, and is also offset inwards from a stationary side panel of the cabinet 402. This positioning of the rotation axis 410 advantageously provides for the door 406 to rotate with a smaller arc or footprint than if the axis was at another location, such as at the edge of the cabinet. The hinge assembly 414 also has a door clearance recess 420 that is configured to receive a portion of the door during the rotation of the door 406. As seen in FIG. 6, a portion of the door is within the door clearance recess 420.

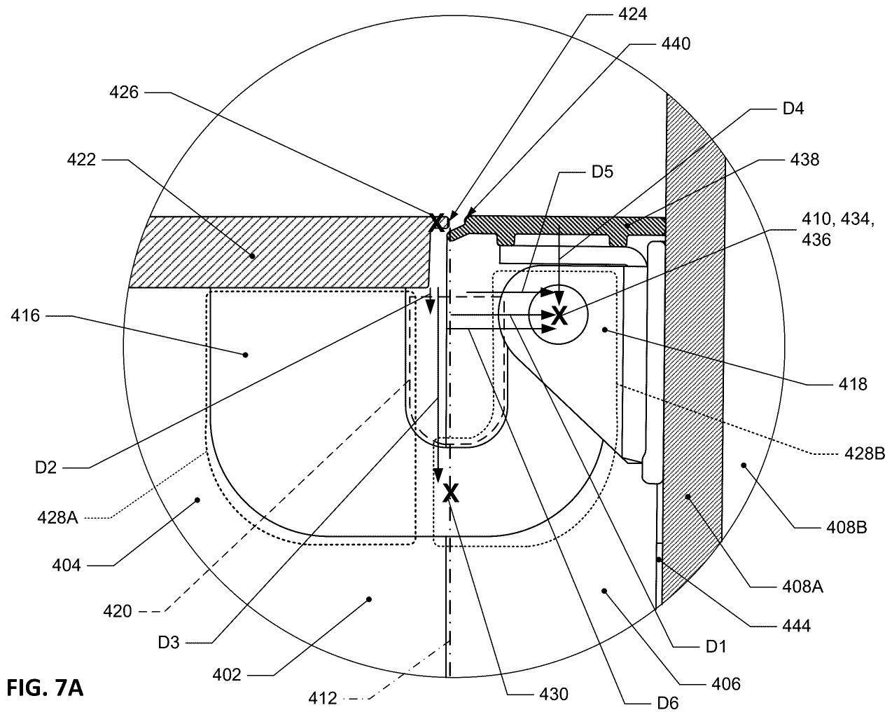

To further understand the configurations of the hinge assembly and movement of the door, FIGS. 7A-7C depict cross-sectional top views of a simplified portion of the electronic gaming machine while the door is in a closed position and in two open positions. In these Figures, the view is along the rotation axis and various features of the EGM 400 have been removed for clarity. In FIG. 7A, the door 406 is in the closed position like in FIG. 4. The cabinet 402 has the internal compartment 404, opening 412 (represented by a dash-dot-dash line), and stationary side panel 422. The stationary side panel 422 partially defines the internal compartment 404 and opening 412, and has a first edge 424 (a small heavy-weight line) along a first axis 426 (this axis is shown offset from the first edge for clarity). The first edge 424 may define an outside or external portion of the cabinet 402. In some embodiments, the first axis 426 may be parallel to the rotation axis 410 and in some instances the first axis 426 may be linear. In some embodiments, the first edge may be planar while in others it may be curved or non-planar. In this example, the portion of the first edge 424 is planar.

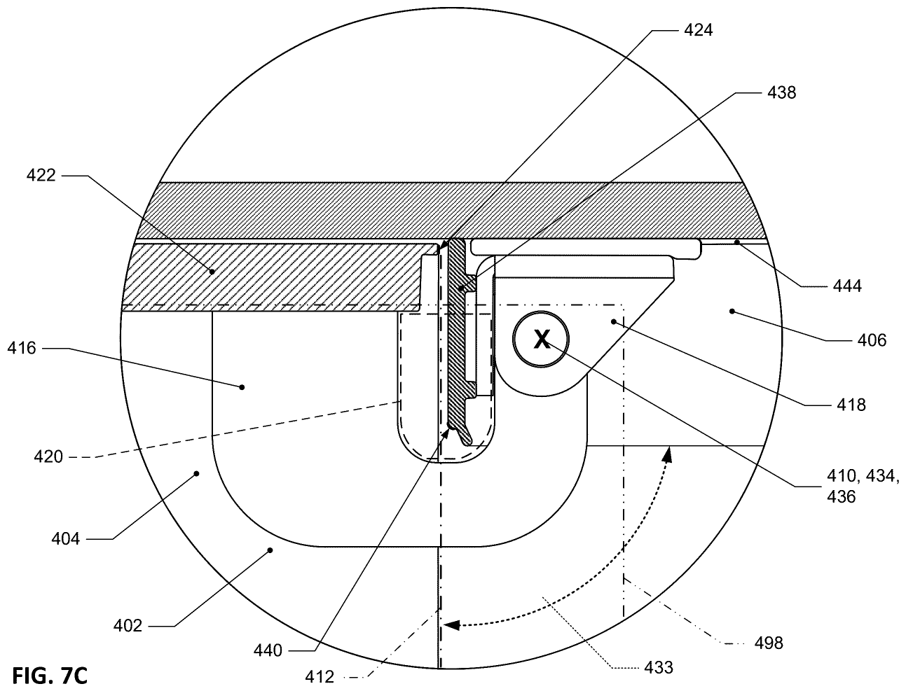

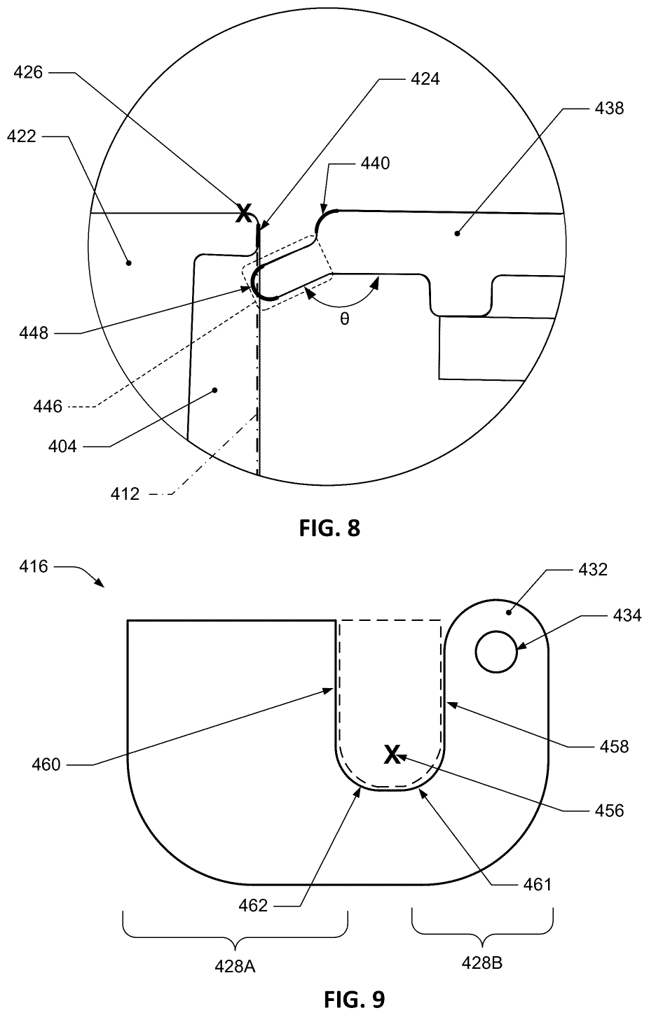

The stationary arm structure 416 of the hinge assembly (not labeled here for clarity) is also illustrated in FIG. 7A and it has a first portion 428A, encompassed by a dashed shape, that is positioned in the internal compartment 404 and connected to the cabinet 402, which here is stationary side panel 422. In some embodiments, like illustrated, the first portion 428A is mounted to the stationary side panel 422. The stationary arm structure 416 also has a second portion 428B, encompassed by another dotted shape, that extends through the opening 412 at a first point 430 and has a distal end (which is covered by the rotation bracket here, but visible in FIGS. 9 and 10) outside the internal compartment 404 with a first pivot point 434. The first pivot point 434 is outside the internal compartment 404 and offset from the opening 412, such as by a first distance D1 perpendicular to the opening 412. The first pivot point 434 is also closer to the stationary side panel 422 than the first point 430 when viewed along the first axis 426 or along the rotation axis 410. For example, as illustrated the first pivot point 434 is offset by a second distance D2 from the stationary side panel 422 in a direction parallel to the opening 412, or perpendicular to the stationary side panel 422. The first point 430 is offset by a third distance D3 greater than the second distance D2 from the stationary side panel 422 in a direction parallel to the opening 412, perpendicular to the stationary side panel 422, or perpendicular to the first axis 426.

A portion of the door 406 is also shown in FIG. 7A. The door 406 has the display devices 408A and 408B connected thereto, along with a door side panel 438 with a second edge 440 parallel to the first axis 426. In the illustrated example, the first edge 424 of the stationary side panel 422 is parallel, or substantially parallel (e.g., within 5% or 10%), to the second edge 440 of the door side panel 438. The rotation bracket 418 of the hinge assembly is connected to the door 406, such as to the portion that also supports the display devices 408A and 408B, and has a second pivot point 436. The second pivot point 436 is positioned within the door 406 and offset from the second edge 440 by a fourth distance D4 in a direction perpendicular to the side panel 422 and by a fifth distance D5 in a direction parallel to the side panel 422. As shown in FIG. 7A, the first pivot point 434 overlaps with the second pivot point 436 of the rotation bracket 418, and these pivot points 434 and 436 are rotatably connected together to form the rotation axis 410. In some implementations, like shown, the rotation connection is via a pin that extends through each pivot point 434 and 436 which are holes. As can be seen, the rotation axis is positioned within the door 406. The door 406 is also configured to rotate about the rotation axis 410 relative to the cabinet 402.

As also seen in FIG. 7A, the stationary arm structure has the door clearance recess 420 that is configured to receive some of the door 406 during opening of the door 406. The first portion 428A and the second portion 428B of the stationary arm structure 416 at least partially define the door clearance recess 420 that is outlined with a dashed shape. In the door closed position of FIG. 7A, the second edge 440 of the door side panel 438 is outside the door clearance recess 420. In some implementations, no structures of the door 406 are positioned inside the door clearance recess 420 while the door 406 is closed. For example, in the closed position, the door side panel 438 is positioned outside the door clearance recess 420.

In some implementations, a portion of the door side panel 438 is configured to move within the door clearance recess 420 while the door is open and being opened. In FIG. 7B, the door 406 is in a partially opened position and as can be seen, some portion of the door side panel 438, including the second edge 440, is positioned inside the door clearance recess 420, e.g., within the dashed boundary of the door clearance recess 420. The door 406 in FIG. 7B may be considered in the same partially open position as in FIGS. 5 and 6. For example, in FIG. 6, the second edge 440 and some of the door side panel 438 are inside the door clearance recess 420 (partially shown with a dashed-line outline).

In FIG. 7C, the door is in a fully opened position which may be the door being opened at a 90 degree, or substantially 90 degree angle (e.g., within 5% or 10%), with respect to the opening 412. This opening angle, angle 433, may be a requirement for some EGMs. As illustrated, some of the door side panel 438 and the second edge 440 have moved within the door clearance recess 420 during the opening of the door 406. Given the configuration of the hinge assembly 414, cabinet 402, and door 406, the door 406 would not be able to rotate about the rotation axis 410 without the door clearance recess 420. The door clearance recess 420 is thereby configured to receive aspects of the door 406 and allow for the rotation of the door 406 about the rotation axis 410.

Referring back to FIG. 7A, the spacing of the stationary arm structure 416 and the second pivot point 436 may be further configured to permit the portion of the door 406 to move within the door clearance recess 420. For instance, the third distance D3 of the first point 430 from the stationary side panel 422 is greater than the fifth distance D5 of the second pivot point 436 from the door side panel 438 in the direction parallel to the door side panel 438. In some instances, the third distance D3 may be no more than 25% larger than the fifth distance D5, thereby permitting the portion of the door 406 to move within the door clearance recess 420. If the third distance is larger than 25% of the fifth distance D5, then the door may not fit within or be able to enter the door clearance recess 420, in some implementations.

In some embodiments, like in FIG. 7A, when the door 406 is in the closed position, the stationary side panel 422 and the door side panel 438 are parallel, or substantially parallel (e.g., within 1%, 5%, or 10% of parallel), to each other. When the door 406 is in fully open position, like in FIG. 7C, the stationary side panel 422 and the door side panel 438 are perpendicular, or substantially perpendicular (e.g., within 1%, 5%, or 10% of perpendicular), to each other. Similarly, the door 406 may have a door front surface 444, such as a surface to which one or more of the display devices are mounted, and when the door is in the closed position, like in FIG. 7A, the door front surface 444 may be perpendicular, or substantially perpendicular (e.g., within 1%, 5%, or 10% of perpendicular), to the stationary side panel 422. When the door 406 is in a fully open position, like in FIG. 7C, the door front surface 444 may be parallel, or substantially parallel (e.g., within 1%, 5%, or 10% of parallel), to the stationary side panel 422.

As further illustrated in FIGS. 5 and 7A-7C, the stationary arm structure 416, including its first pivot point 434, remain stationary relative to the cabinet 402 at all times. When the door is open, closed, or moving from open to closed, the stationary arm structure 416 does not move, is not intended to move, and does not have movable parts. Similarly, the stationary side panel 422 of the cabinet remains stationary and does not move. Also, the rotation bracket 418 remains stationary relative to the door 406, including while the door 406 is open, closed, or moving therebetween.

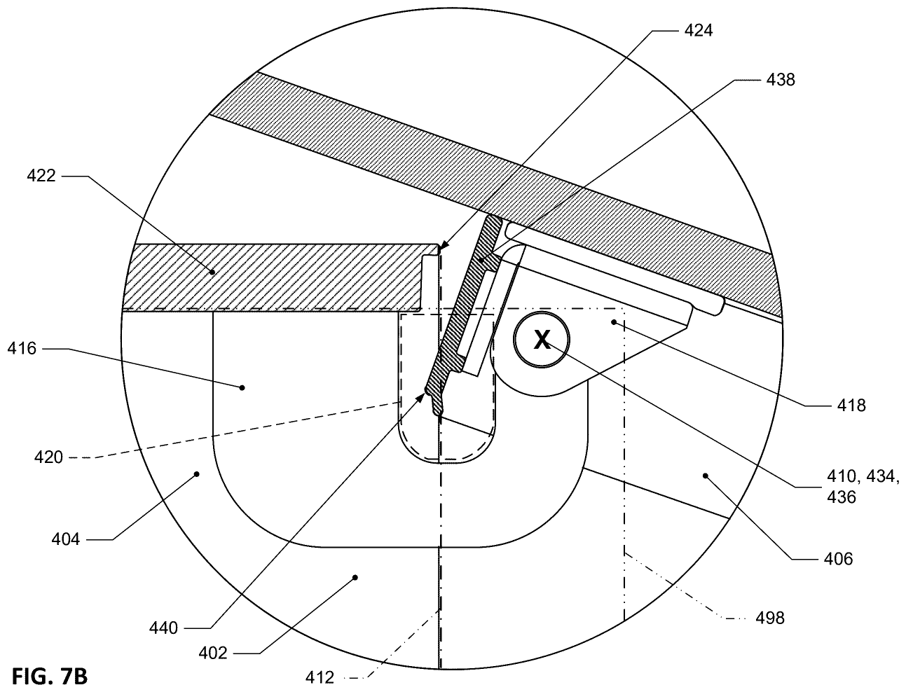

In some implementations, the door 406 may have various security features that prevent or restrict access to the internal compartment 404. One such security feature is a security flange identified in FIG. 8 which depicts a magnified, detail view of the simplified portion of the electronic gaming machine of FIG. 7A. For clarity here, the cross-hatching has been removed. A section of the stationary side panel 422 and its first edge 424 are shown along with some of the opening 412. The door side panel 438 has the second edge 440 and a security flange 446 having a security flange edge 448. When in the closed position as illustrated in FIGS. 7A and 8, the security flange edge 448 and some of the security flange 446 extend through the opening 412 and into the internal compartment 404. In some instances, when in the closed position, the security flange 446 and the stationary side panel 422 may overlap with each other. For example, when viewed along the rotation axis 410, like in FIG. 8, the stationary side panel 422 overlaps with the security flange 446 in a direction perpendicular to the rotation axis 410 or opening 412. In some embodiments, the security flange 446 may also be offset from the second pivot point 436 in a direction perpendicular to the opening 412 by a sixth distance D6 that is greater than the first distance D1, as illustrated in FIG. 7A. There, the sixth distance D6 is parallel to and greater than the first distance D1.

The security flange may also be oriented at various angles with respect to the door side panel. In some embodiments, the security flange 446 and the door side panel 438 define an included angle θ that is obtuse as illustrated in FIG. 8. The obtuse included angle θ may range between 160 degrees and 120 degrees. This obtuse included angle θ may advantageously restrict and prevent access to the internal compartment while providing movability of the door 406.

The cabinet and/or door may have additional security flanges that further prevent or restrict access to the internal compartment through the gap between the door and cabinet when the door is closed. As shown in FIG. 5, some implementations have the cabinet 402 with a top panel 450 that further defines the opening 412 and that has a second security flange 452 configured to extend into the door 406 when the door 406 is in the closed position. When viewed at a top angle, like along the rotation axis 410 or the first axis 426, a top panel 454 of the door 406 overlaps the second security flange 452. In some implementations, the second security flange 452 on the cabinet 402 may provide support for the door 406 which can prevent unwanted and unauthorized movement or tampering of the door downwards towards a floor on which the EGM 400 is directly or indirectly supported.

Additional or alternative features of the hinge assembly and stationary arm structure will now be discussed. FIG. 9 depicts a top view of the stationary arm structure according to disclosed embodiments. The stationary arm structure 416 has the first portion 428A and the second portion 428B with the first pivot point 434 on the distal end 432 of the second portion 428B. The door clearance recess 420 is the area outlined by the dashed shape. In some embodiments, the door clearance recess 420 is partially defined by the first portion 428A and the second portion 428B and extends at least 90 degrees around a second axis 456 that is parallel to the first axis 426. In the example of FIG. 9, the door clearance recess 420 extends around the second axis 456 by at least 180 degrees. The door clearance recess 420 may also be defined by a first linear surface 458 of the second portion 428B, a second linear surface 460 of the first portion 428A, and a curved surface 462 that spans between the first linear surface 458 and the second linear surface 460.

In some embodiments, the stationary arm structure has a first arm and a second arm offset below the first arm. FIG. 10 depicts an off-angle view of the stationary arm structure of FIG. 9, according to disclosed embodiments. FIGS. 5 and 6 also depict this same stationary arm structure 416. Here in FIG. 10, the stationary arm structure 416 has a first arm 464 and a second arm 466 offset below the first arm 464. Both the first arm 464 and the second arm 466 have their own respective first portion 428A, second portion 428B, door clearance recess 420, first pivot point 434, and distal end 432; these features for the first arm 464 have a “-1” after their identifier and for the second arm 466 have a “-2” after their identifier. The first pivot points 434-1 and 434-2 together with the rotation bracket 418 make up the rotation axis 410, like illustrated in FIG. 6. The stationary arm structure 416 may also have a support member 468 connected to and spanning between the first arm 464 and the second arm 466 to provide additional strength to the stationary arm structure 416. By having two arms, and the support member in some implementations, the stationary arm structure can provide additional support for the weight of the door and additional strength in preventing sagging of the door, tampering, and unauthorized access to the internal compartment.

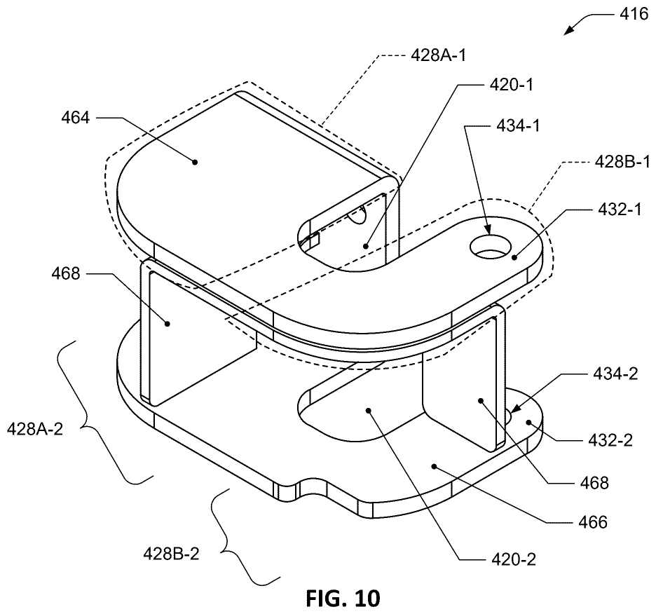

In some embodiments, some terminology of the hinge assembly may differ. FIG. 11 depicts an off-angle view of the stationary arm structure of FIG. 10, according to various embodiments. Here, the stationary arm structure 1116 has a first proximal end 1170 with a first mounting interface 1172 configured to be mounted to a first surface, such as the stationary side panel 422 of the cabinet 402 as illustrated in FIGS. 6 and 7A. The stationary arm structure 1116 also has the first distal end 1132 with the first pivot point 1134, and a body 1174 spanning between the first proximal end 1170 and the distal end 1132. The body 1174 also extends around at least 90 degrees of a center axis 1176 to define the door clearance recess 1120, like described above in FIG. 9 and with respect to the axis 461.

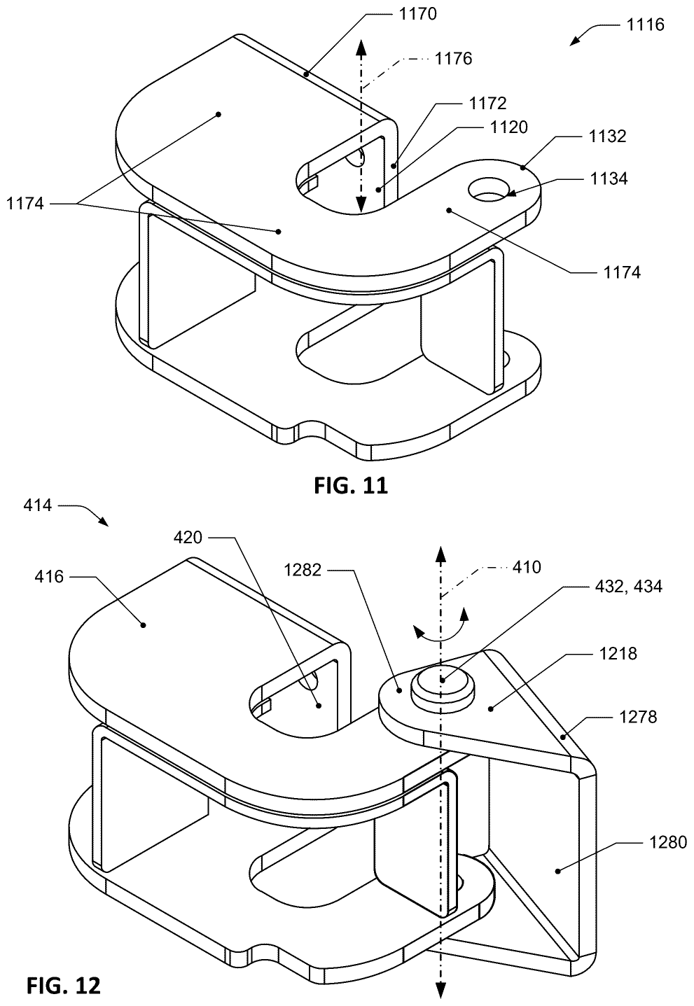

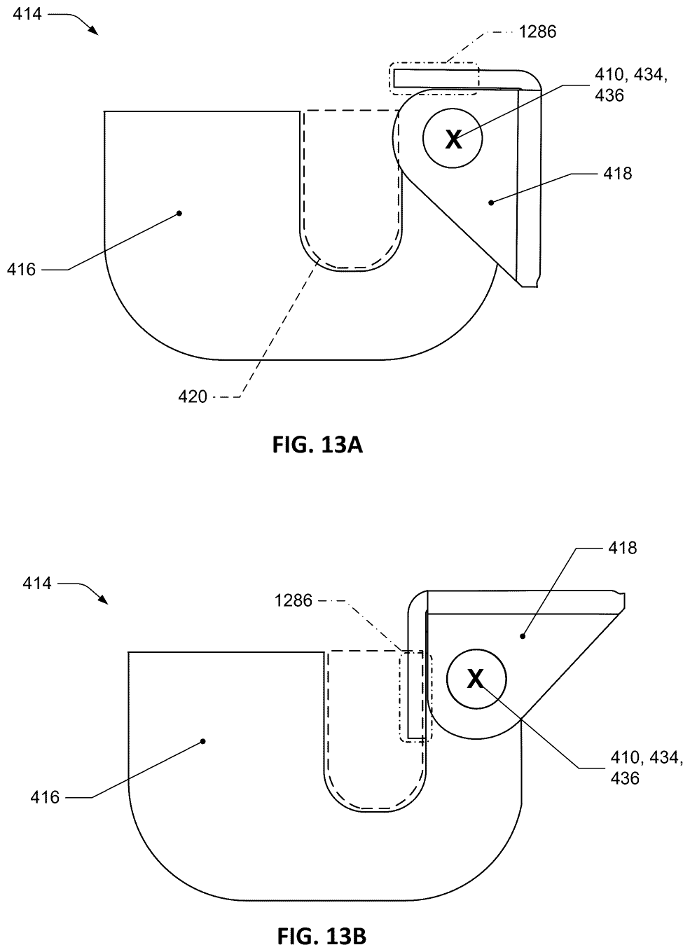

FIG. 12 depicts an off-angle view of a hinge assembly according to various embodiments. The hinge assembly 414 here is the same as shown in FIGS. 5-7C and may have the same or different terminology as provided above. For example, the stationary arm structure 416 has the features described above with respect to FIGS. 5-10 as well as those of FIG. 11, such as the door clearance recess 420/1120. The hinge assembly 414 also has the rotation bracket 418 which may also be considered a rotation plate 1218; for simplicity, these features will be collectively referred to as the rotation bracket/plate 1218 in FIGS. 12-13B and they may be the same feature, in some embodiments. This rotation bracket/plate 1218 has a second proximal end 1278 with a second mounting interface 1280 configured to be mounted to a second surface, such as a surface of the door as shown in FIG. 6. The second surface to which the rotation bracket/plate 1218 is mounted is separate from the first surface to which the stationary arm structure 416 is mounted, such as the door and cabinet, respectively. The rotation bracket/plate 1218 has a second distal end 1282 that has the second pivot point 436. The first and second pivot points 434 and 436 are rotatably connected to each other, such as by a pin, to form the rotation axis 410 about which the rotation bracket/plate 1218 rotates with respect to the stationary arm structure 416.

Similar to the illustration of FIGS. 7A-7C, the rotation plate 1218 is configured to be rotated between a first position and a second position with respect to the stationary arm structure. FIGS. 13A and 13B depict top views of the hinge assembly of FIG. 12 in various configurations according to disclosed embodiments. In FIG. 13A, like in FIG. 7A, the rotation bracket/plate 1218 is in a first position and has a first portion 486, encompassed by a dotted shape, that is positioned outside the door clearance recess 420. As described herein, the rotation bracket/plate 1218 is configured to rotate about the rotation axis 410 with respect to the stationary arm structure 416. In FIG. 13B, like in FIG. 7C, the rotation bracket/plate 1218 is in a second position and the first portion 486 is positioned inside the door clearance recess 420.

As also provided above with respect to FIGS. 7A-8, in some embodiments the hinge assembly 414 may be a secure door hinge assembly that has various sections and the security flange. For example, referring to FIG. 7A, the secure door hinge assembly may have the stationary arm structure 416, rotation bracket 418, and a door section that may be the same as, or a part of, the door side panel 438 such that the door section is connected to the rotation bracket 418 and has a door edge, such as the second edge 440. This door edge, or second edge 440, is offset from the second pivot point 436 by the fourth distance D4 and in the first position like in FIG. 7A, the door edge is outside the door clearance recess 420. In the second position like in FIG. 7C, the door edge is inside the door clearance recess 420. In some embodiments, the secure door hinge assembly may also have a side connected to the stationary arm structure, which may be a part of, or the same as, the stationary side panel 422. As illustrated in FIG. 8, the door section may also have the security flange that extends past the door edge and overlaps with the stationary side panel 422 when in the first, or door closed, position. In the second position, or door open position, the security flange is also positioned inside the door clearance recess as shown in FIGS. 7B and 7C.

Configuring the hinge assembly as provided herein, including positioning the rotation axis within the door 406, allows for advantageous rotation of the door. For instance, the rotational arc of the door is shifted inwards towards the internal compartment, as opposed to at the edge of the cabinet, such that the door's outermost point has a smaller arc that it travels while opening thereby having a smaller footprint or clearance area without obstructions needed when opening. FIG. 14 depicts a cross-sectional top view of the electronic gaming machine of FIG. 4 in accordance with disclosed embodiments. For clarity, the cross-hatching has been removed. The door 406 here is in the closed position and as it opens from the closed position, the door 406 travels through a sector 488 or arc 492 which must be free from obstructions, such as other adjacent EGMs. An outermost portion 486 of the door 406, which is on the display 408B, defines the outermost arc 492 of the movement path for the door 406. The door 406 traverses the sector 488, shown with shading and a dashed boundary that represents the arc 489, during opening and closing. By configuring the rotation axis 410 inwards from the outer boundary 490 of the cabinet 402, the sector 488 and corresponding arc 489 are smaller than if the rotational axis was at the edge of the cabinet, like with a traditional piano-style hinge. In FIG. 14, arc 492 represents the rotational arc of the door 406 if the hinge or rotation axis was on the edge 490 of the cabinet 402. As can be seen, arc 489 is offset from the edge 490 by a seventh distance D7 and arc 492 is offset from the edge by an eight distance D8 larger than the seventh distance D7. Because of various spacing constraints in particular locations, such as casinos, there are obstructions like adjacent EGMs and this arc 489 can prevent the door from striking other EGMs during opening and closing.

In some embodiments, the cabinet and door define a footprint when in the closed position and aspects of the hinge assembly and door remain within this footprint during opening and closing of the door. For example, in FIG. 14, a footprint 498, having a dash-dot-dash boundary, is defined by the cabinet 402 and door 406 while the door 406 is in the closed position. The stationary arm structure 416 and rotation axis 410 are within the footprint 498 and remain therein while the door 406 is opening and open. Referring back to FIGS. 7B and 7C, a portion of the footprint 494 is shown and when opening and in the open position, the portion of the door within the door clearance recess 420 is also within the footprint 494.

It is to be understood that the phrases “for each <item>of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

While the disclosure has been described with respect to the figures, it will be appreciated that many modifications and changes may be made by those skilled in the art without departing from the spirit of the disclosure. Any variation and derivation from the above description and figures are included in the scope of the present disclosure as defined by the claims.

What is claimed is:

1. An electronic gaming machine, comprising:
a cabinet defining an internal compartment and an opening that provides access to the internal compartment, and having a stationary side panel at least partially defining the internal compartment and opening and having a first edge along a first axis;
a door configured to support one or more display devices and having a door side panel with a second edge parallel to the first axis; and
a hinge assembly having:
a stationary arm structure having a first portion positioned in the internal compartment and connected to the cabinet, and a second portion extending through the opening at a first point and having a distal end outside the internal compartment with a first pivot point, and
a rotation bracket connected to the door and having a second pivot point, wherein:
the first pivot point is offset from the opening and closer to the stationary side panel than the first point when viewed along the first axis,
the second pivot point is offset from the second edge within the door by a first distance perpendicular to the door side panel and a second distance parallel to the door side panel,
the second portion at least partially defines a door clearance recess,
the first pivot point and the second pivot point are rotatably connected to each other to form a rotation axis,
the door is configured to rotate about the rotation axis relative to the cabinet between a closed position and an open position, and
a portion of the door side panel including the second edge is configured to move within the door clearance recess during rotation of the door about the rotation axis.

2. The electronic gaming machine of claim 1, wherein:
the stationary arm structure and the first pivot point remain stationary relative to the cabinet, and
the rotation bracket remains stationary relative to the door.

3. The electronic gaming machine of claim 1, wherein the first portion of the stationary arm structure is mounted to the stationary side panel.

4. The electronic gaming machine of claim 1, wherein the rotation bracket is mounted to the door side panel.

5. The electronic gaming machine of claim 1, wherein the door clearance recess:
is further partially defined by the first portion, and
the door clearance recess extends around at least 90 degrees of a second axis parallel to the first axis.

6. The electronic gaming machine of claim 5, wherein the door clearance recess is defined by:
a first linear surface of the second portion,
a second linear surface of the first portion, and
a curved surface of the first portion and/or the second portion spanning between the first linear surface and the second linear surface.

7. The electronic gaming machine of claim 1, wherein:
in the closed position, the portion of the door side panel and the second edge are outside the door clearance recess, and
in the open position, the portion of the door side panel and the second edge are positioned inside the door clearance recess.

8. The electronic gaming machine of claim 1, wherein:
in the closed position, the stationary side panel and the door side panel are substantially parallel to each other, and
in the open position, the stationary side panel and the door side panel are substantially perpendicular to each other.

9. The electronic gaming machine of claim 8, wherein:
the door further includes a door front surface substantially perpendicular to the door side panel, and
in the open position, the stationary side panel and the door front surface are substantially parallel to each other.

10. The electronic gaming machine of claim 1, wherein:
the first point is offset from the first edge by a third distance in a direction perpendicular to the first axis and parallel to the opening,
the first pivot point is:
offset from the opening by a fourth distance in a direction perpendicular to the opening, and
offset from the first edge by a fifth distance in the first direction, and the fifth distance is less than the third distance.

11. The electronic gaming machine of claim 1, wherein:
the first point is offset from the first edge by a third distance in a direction perpendicular to the first axis and parallel to the opening, and
the third distance is greater than the second distance.

12. The electronic gaming machine of claim 11, wherein the third distance is no more than 25% larger than the second distance.

13. The electronic gaming machine of claim 1, wherein:
the door side panel further has a security flange with a security flange edge,
the security flange extends past the second edge by a seventh distance such that when viewed along the first axis, the security flange edge is farther from the second pivot point in a direction parallel to the door side panel than the second edge, and
when in the closed position, the security flange edge extends through the opening and into the internal compartment.

14. The electronic gaming machine of claim 13, wherein the security flange and the door side panel define an included angle that is obtuse.

15. The electronic gaming machine of claim 13, wherein:
the cabinet further comprises a top panel partially defining the opening and having a second security flange, and
when in the closed position, the door overlaps the second security flange when viewed along the first axis.

16. The electronic gaming machine of claim 1, wherein:
the stationary arm structure further has a first arm, a second arm offset below the first arm in a direction parallel to the first axis, and a support member connected to and spanning between the first arm and the second arm,
the first portion includes a first section of the first arm and a first section of the second arm, and
the second portion includes a second section of the first arm and a second section of the second arm.

17. The electronic gaming machine of claim 1, wherein:
when viewed along the first axis, the cabinet and the door define a footprint,
the stationary arm structure and the rotation axis are positioned within the footprint and are configured to remain stationary relative to the cabinet during movement of the door, and
in the open position, the portion of the door and the second edge are within the footprint.

18. A secure door hinge assembly, comprising:
a stationary arm structure having:
a first proximal end with a first mounting interface configured to be mounted to a first surface,
a first distal end having a first pivot point, and
a body spanning between the first proximal end and the first distal end, and extending around at least 90 degrees of a center axis to define a door clearance recess; and
a rotation plate having:
a second proximal end with a second mounting interface configured to be mounted to a second surface separate from the first surface, and
a second distal end having a second pivot point, wherein:
the first pivot point and the second pivot point are rotatably connected to each other to form a rotation axis such that the rotation plate is configured to rotate about the rotation axis with respect to the stationary arm structure,
the rotation plate is configured to rotate between a first position and a second position,
in the first position, a first portion of the rotation plate is positioned outside the door clearance recess, and
in the second position, the first portion of the rotation plate is positioned inside the door clearance recess.

19. The secure door hinge assembly of claim 18, further comprising a door section having a door edge and connected to the rotation plate, wherein:
the door edge is offset from the second pivot point by a first distance when viewed along the rotation axis,
in the first position, the door edge and a second portion of the door section are outside the door clearance recess, and
in the second position, the door edge and the second portion of the door section are inside the door clearance recess.

20. The secure door hinge assembly of claim 19, further comprising a side connected to the stationary arm structure and having a side edge, wherein:
the door section further has a security flange extending past the door edge,
in the first position:
the door edge is adjacent to the side edge,
the security flange extends past the side edge and overlaps with the side when viewed along the rotation axis,
the security flange is outside the door clearance recess, and
in the second position, the security flange is positioned inside the door clearance recess.
